(19) United States
(12) Patent Application Publication
(10) Pub. No.: US 2026/0068157 A1
(43) Pub. Date: Mar. 5, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Yoonjo Hwang, Suwon-si (KR); Dongseog Eun, Suwon-si (KR)

(21) Appl. No.: 19/093,383

(22) Filed: Mar. 28, 2025

(30) Foreign Application Priority Data
Aug. 29, 2024 (KR) 10-2024-0116573

(51) Int. Cl. H10B 41/40; H01L 21/768; H01L 23/00; H01L 25/065; H10B 41/10; H10B 41/27; H10B 43/10; H10B 43/27; H10B 43/40; H10B 80/00

(52) U.S. Cl. CPC H10B 41/40; H10B 41/27; H10B 43/27; H10B 43/40; H10B 41/10; H10B 43/10; H10B 80/00

(57) ABSTRACT

A semiconductor device includes gate electrodes stacked in a first direction and extending in a second direction, channel structures extending in the first direction into the gate electrodes, contact plugs extending in the first direction and electrically connected to the gate electrodes, respectively, and contact liner layers on side surfaces of the contact plugs, respectively. Portions of the contact plugs may extend into at least one of the gate electrodes. The contact liner layers may include a first contact liner layer on a side surface of a first contact plug and having a maximum thickness in the second direction as a first thickness, and a second contact liner layer on a side surface of a second contact plug and including a lower region having the first thickness and an upper region having a second thickness in the second direction that is greater than the first thickness.

### CROSS-REFERENCE TO RELATED APPLICATIONS

This application claims benefit of priority to Korean Patent Application No. 10-2024-0116573 filed on Aug. 29, 2024, in the Korean Intellectual Property Office, the disclosure of which is incorporated herein by reference in its entirety.

### BACKGROUND OF THE INVENTION

The present disclosure relates to semiconductor devices and data storage systems including the same.

In a data storage system requiring data storage, semiconductor devices capable of storing large amounts of data are helpful. Accordingly, methods of increasing the data storage capacity of semiconductor devices are being studied. For example, as one of the methods of increasing the data storage capacity of semiconductor devices, a semiconductor device including memory cells arranged three-dimensionally, instead of two-dimensionally, has been proposed.

### SUMMARY OF THE INVENTION

Aspects of the present disclosure provide a semiconductor device having improved reliability and integration.

Aspects of the present disclosure provide a data storage system including a semiconductor device having improved reliability and integration.

A semiconductor device according to example embodiments of the present disclosure may include a plate layer; gate electrodes spaced apart from each other and stacked in a first direction perpendicular to an upper surface of the plate layer, the gate electrodes extending in a second direction perpendicular to the first direction along first and second regions; channel structures in the first region and extending in the first direction into the gate electrodes; contact plugs extending in the first direction and electrically connected to the gate electrodes, respectively, in the second region; and contact liner layers on side surfaces of the contact plugs, respectively, wherein portions of the contact plugs extend into at least one of the gate electrodes, and wherein the contact liner layers comprise a first contact liner layer on a side surface of a first one of the contact plugs, the first contact liner layer having a maximum thickness in the second direction as a first thickness; and a second contact liner layer on a side surface of a second one of the contact plugs, the second contact liner layer including a lower region having the first thickness and an upper region having a second thickness in the second direction that is greater than the first thickness.

A semiconductor device according to example embodiments of the present disclosure may include a plate layer; gate electrodes spaced apart from each other and stacked in a first direction perpendicular to an upper surface of the plate layer; channel structures extending in the first direction into the gate electrodes; contact plugs extending in the first direction and electrically connected to the gate electrodes, respectively; and contact liner layers on side surfaces of the contact plugs, respectively, wherein portions of the contact plugs extend into at least one of the gate electrodes, and wherein a first one of the contact liner layers includes a plurality of regions arranged in the first direction and having different thicknesses in a second direction perpendicular to the first direction, and the thicknesses of the plurality of regions decrease toward the plate layer.

A data storage system according to example embodiments of the present disclosure may include a semiconductor storage device that comprises a first semiconductor structure including circuit elements, a second semiconductor structure on the first semiconductor structure, and an input/output pad electrically connected to the circuit elements; and a controller electrically connected to the semiconductor storage device through the input/output pad and configured to control the semiconductor storage device, wherein the second semiconductor structure comprises a plate layer; gate electrodes spaced apart from each other and stacked in a first direction perpendicular to an upper surface of the plate layer; channel structures extending in the first direction into the gate electrodes; contact plugs extending in the first direction and electrically connected to the gate electrodes, respectively; and contact liner layers on side surfaces of the contact plugs, respectively, wherein portions of the contact plugs extend into at least one of the gate electrodes, and wherein the contact liner layers comprise a first contact liner layer including a region having a first thickness in a second direction perpendicular to the first direction; and a second contact liner layer including a lower region having the first thickness and an upper region having a second thickness in the second direction that is greater than the first thickness, the second contact liner layer having a different length from the first contact liner layer in the first direction.

A semiconductor device having improved reliability and integration and a data storage system including the same may be provided by arranging contact liner layers having various shapes on side surfaces of contact plugs.

Advantages and effects of the present application are not limited to the foregoing content and may be more easily understood in the process of describing example embodiments of the present disclosure hereinafter.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments;

FIGS. 2A and 2B are schematic cross-sectional views of a semiconductor device according to example embodiments;

FIGS. 3 and 4 are partially enlarged views illustrating enlarged portions of a semiconductor device according to example embodiments;

FIGS. 5A and 5B are partially enlarged views of a semiconductor device according to example embodiments;

FIGS. 6A and 6B are cross-sectional views and partially enlarged views of a semiconductor device according to example embodiments;

FIG. 7 is a cross-sectional view of a semiconductor device according to example embodiments;

FIGS. 8A and 8B are cross-sectional views of a semiconductor device according to example embodiments;

FIGS. 9A to 9S are schematic cross-sectional views illustrating a method of manufacturing a semiconductor device according to example embodiments;

FIG. 10 is a schematic view of a data storage system including a semiconductor device according to example embodiments; and

FIG. 11 is a perspective view schematically illustrating a data storage system including a semiconductor device according to example embodiments.

### DETAILED DESCRIPTION

Hereinafter, example embodiments of the present disclosure will be described with reference to the accompanying drawings.

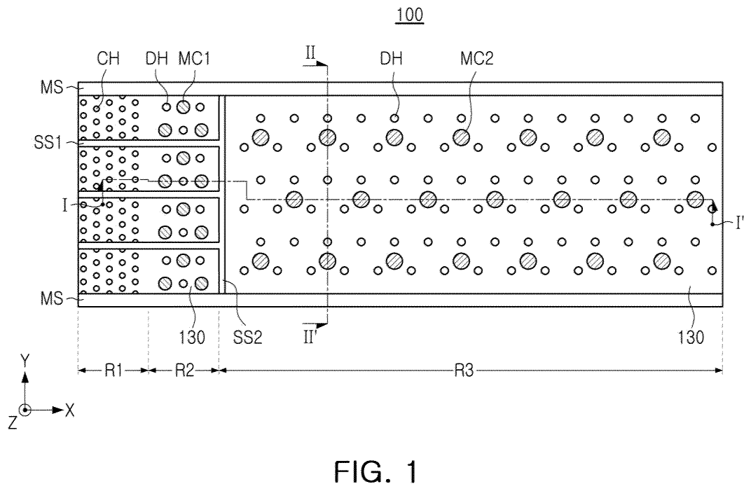

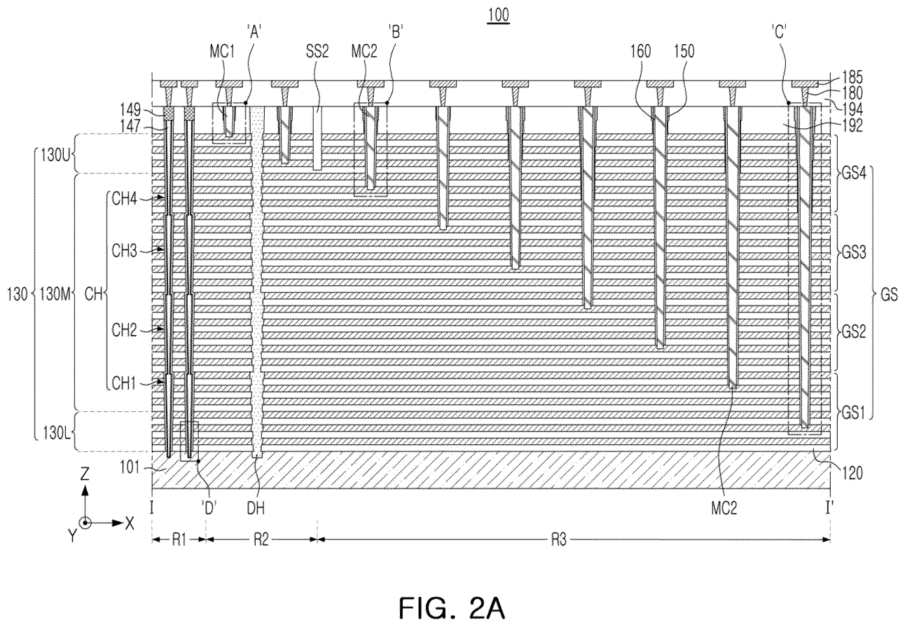

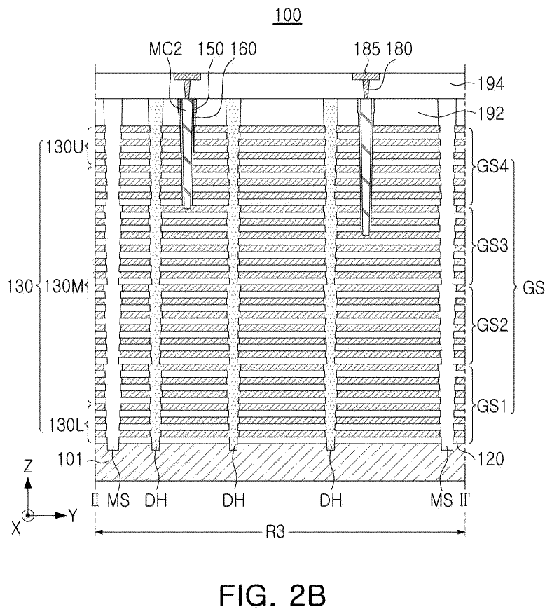

FIG. 1 is a schematic plan view of a semiconductor device according to example embodiments. FIGS. 2A and 2B are schematic cross-sectional views of a semiconductor device according to example embodiments. In particular, FIGS. 2A and 2B illustrate cross-sectional views taken along lines I-I′ and II-II′ of FIG. 1, respectively.

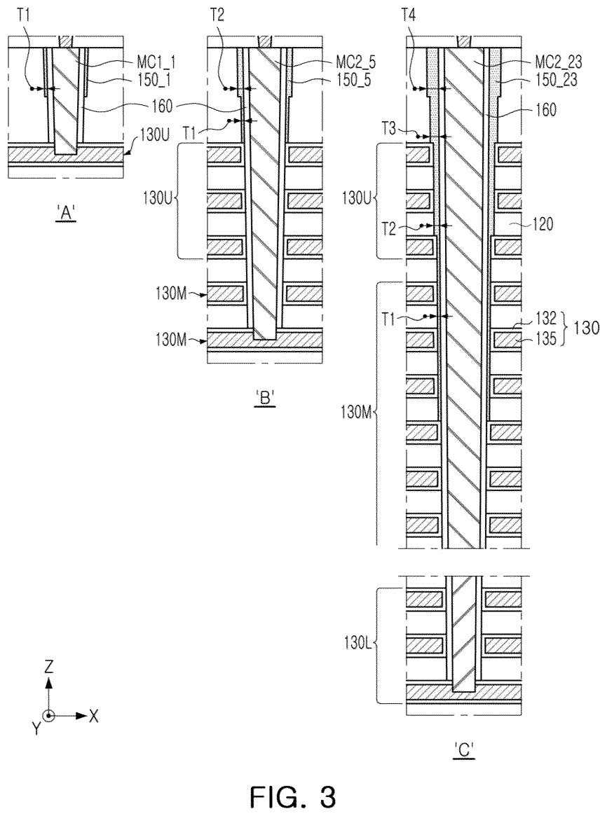

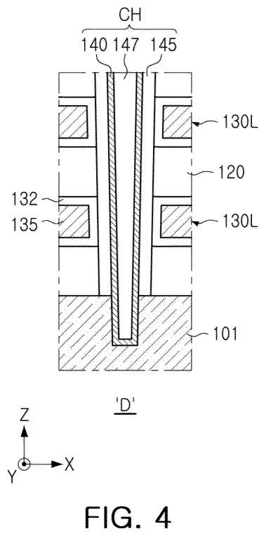

FIGS. 3 and 4 are partially enlarged views illustrating enlarged portions of a semiconductor device according to example embodiments. In particular, FIG. 3 is an enlarged view of region ‘A’, region ‘B’ and region ‘C’ of FIG. 2A, and FIG. 4 is an enlarged view of region ‘D’ of FIG. 2A.

Referring to FIGS. 1, 2A, 2B, 3, and 4, a semiconductor device 100 may include first to third regions R1, R2 and R3. The semiconductor device 100 may include a plate layer 101, gate electrodes 130 stacked on the plate layer 101 and included in a gate structure GS, interlayer insulating layers 120 alternately stacked with the gate electrodes 130 and included in the gate structure GS, channel structures CH disposed to penetrate through (i.e., extend into) the gate structure GS in a first region R1, gate separation regions MS extending by penetrating through the gate structure GS in first to third regions R1, R2 and R3, first and second upper separation regions SS1 and SS2 penetrating through upper gate electrodes 130U disposed on upper portions of the gate electrodes 130, first contact plugs MC1 connected to the upper gate electrodes 130U in the second region R2 and extending vertically (e.g., in a Z-direction), second contact plugs MC2 connected to memory gate electrodes 130M and lower gate electrodes 130L in the third region R3 and extending vertically, and dummy vertical structures DH disposed around the first and second contact plugs MC1 and MC2. As used herein, the second region R2 where the first contact plugs MC1 are physically and/or electrically connected to the upper gate electrodes 130U and the third region R3 where the second contact plugs MC2 are physically and/or electrically connected to the memory gate electrodes 130M and the lower gate electrodes 130L may be referred to together as a second region. In other words, the second region R2 and the third region R3 may be referred to together as a second region (R2 and R3).

The semiconductor device 100 may further include contact liner layers 150 and contact spacers 160 surrounding the first and second contact plugs MC1 and MC2, studs 180, cell interconnection lines 185, and first and second cell region insulating layers 192 and 194. It will be understood that “an element A surrounds an element B” (or similar language) as used herein means that the element A is at least partially around the element B but does not necessarily mean that the element A completely encloses the element B.

In the semiconductor device 100, the first region R1 may be a region in which channel structures CH are disposed and may be a region in which memory cells are disposed. The second and third regions R2 and R3 may correspond to regions for electrically connecting the gate electrodes 130 to circuit elements (not shown). The second and third regions R2 and R3 may be arranged sequentially from the first region R1, at least in one end of the first region R1, at least in one direction, for example, in an X-direction. The first contact plugs MC1 may be disposed in the second region R2, and the second contact plugs MC2 may be disposed in the third region R3. Depending on the description manner, the first to third regions R1, R2 and R3 may be referred to as regions of the plate layer 101, not regions of the semiconductor device 100.

The plate layer 101 may have a plate shape and may function as at least a portion of a common source line of the semiconductor device 100. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer such as a polycrystalline silicon layer or an epitaxial layer.

The gate electrodes 130 may be vertically spaced apart from each other and stacked on the plate layer 101 and included in the gate structure GS together with the interlayer insulating layers 120. The gate structure GS may include first to fourth stack structures GS1, GS2, GS3 and GS4 vertically stacked. However, according to example embodiments, the number of stack structures included in the gate structure GS may be variously changed. For example, in some example embodiments, the gate structure GS may be formed of less than four stack structures or five or more stack structures, or may be formed of a single stack structure. The number of gate electrodes 130 included in each of the first to fourth stack structures GS1, GS2, GS3 and GS4 may be identical to or different from each other.

The gate electrodes 130 may include upper gate electrodes 130U included in string select transistors and erase transistors, memory gate electrodes 130M included in a plurality of memory cells, and lower gate electrodes 130L included in ground select transistors. The number of memory gate electrodes 130M may be determined according to the capacity of the semiconductor device 100. In some example embodiments, the upper gate electrodes 130U may not include an erase transistor. In some example embodiments, the lower gate electrodes 130L may further include a gate electrode included in the erase transistor. According to example embodiments, the number of gate electrodes 130 included in the upper gate electrodes 130U and the lower gate electrodes 130L may be variously changed. Some of the gate electrodes 130, for example, the memory gate electrodes 130M adjacent to the upper gate electrodes 130U and/or the lower gate electrodes 130L, may be dummy gate electrodes.

As illustrated in FIG. 1, the gate electrodes 130 may be disposed to be separated from each other in a Y-direction by gate separation regions MS extending continuously in the first to third regions R1, R2 and R3. The gate electrodes 130 between a pair of gate separation regions MS may form one memory block, but the range of the memory block is not limited thereto.

The gate electrodes 130 may be vertically spaced from each other and stacked in the first to third regions R1, R2 and R3. The gate electrodes 130 do not form a stepped shape, and all gate electrodes 130 may have a vertically stacked shape in the first to third regions R1, R2 and R3. The gate electrodes 130 may extend by the same length in a horizontal direction in the first to third regions R1, R2 and R3. Accordingly, the second contact plugs MC2 and some of the first contact plugs MC1 may penetrate through at least one gate electrode 130 from an upper portion and may be connected to the gate electrode 130. Ends of the gate electrodes 130 in the X-direction may be disposed outside the third region R3.

As illustrated in FIGS. 3 and 4, each gate electrode 130 may include a gate barrier layer 132 and a gate conductive layer 135. The gate barrier layer 132 may cover an upper surface and a lower surface of the gate conductive layer 135 and may cover some of side surfaces thereof. It will be understood that “an element A covers a surface of an element B” (or similar language) as used herein means that the element A is on and/or overlaps the surface of the element B but does not necessarily mean that the element A covers the surface of the element B entirely. The gate barrier layer 132 may expose the gate conductive layer 135 on a side surface of the gate electrode 130 in contact with the gate separation regions MS, among side surfaces of the gate electrode 130, and may cover the gate conductive layer 135 on a side surface of the gate electrode 130 in contact with the channel structures CH, the dummy vertical structures DH, the contact liner layers 150, and the contact spacers 160, among the side surfaces of the gate electrode 130.

The gate electrodes 130 may include a conductive material such as a metallic material or a semiconductor material. For example, the gate barrier layer 132 may include tungsten nitride (WN), tantalum nitride (TaN), titanium nitride (TiN), or combinations thereof, and the gate conductive layer 135 may include tungsten (W).

The interlayer insulating layers 120 may be disposed between the gate electrodes 130. Similarly to the gate electrodes 130, the interlayer insulating layers 120 may be spaced apart from each other in a direction, perpendicular to an upper surface of the plate layer 101 (e.g., a Z-direction), and may be disposed to extend in the X-direction. The interlayer insulating layers 120 may include an insulating material such as silicon oxide or silicon nitride. In example embodiments, thicknesses of each of the interlayer insulating layers 120 may be variously changed.

The channel structures CH may extend in a Z-direction by penetrating through the gate electrodes 130 and may be connected to the plate layer 101. Each of the channel structures CH may be included in one memory cell string, and may be spaced apart from each other in rows and columns on the plate layer 101 in the first region R1. The channel structures CH may be disposed to form a grid pattern in an X-Y plane or may be disposed in a zigzag shape in one direction. The channel structures CH have a pillar shape and may have inclined side surfaces that become narrower as the channel structures CH move closer to the plate layer 101. The number of channel structures CH forming a row in the Y-direction and the arrangement shape thereof may be variously changed in embodiments.

Each of the channel structures CH may include first to fourth channel portions CH1, CH2, CH3 and CH4 vertically stacked. The first to fourth channel portions CH1, CH2, CH3 and CH4 may penetrate through the first to fourth gate structures GS1, GS2, GS3 and GS4 of the gate structure GS, respectively. The first to fourth channel portions CH1, CH2, CH3 and CH4 may have a form in which the channel portions are connected to each other, and may have a form in which a width of an upper surface of the channel portion disposed in a lower portion is larger than a width of a lower surface of the channel portion disposed in an upper portion in a region in which the channel portions are connected to each other or an interface between the channel portions. The channel structure CH may have bent portions due to the difference in width in the interface between the first to fourth channel portions CH1, CH2, CH3 and CH4. A lower end of the first channel portion CH1 may be disposed in the plate layer 101.

Each of the channel structures CH may include a channel layer 140, a channel dielectric layer 145, a channel-filled insulating layer 147, and a channel pad 149 disposed in a channel hole. The channel layer 140, the channel dielectric layer 145 and the channel-filled insulating layer 147 may be respectively connected to each other between the first to fourth channel portions CH1, CH2, CH3 and CH4.

As illustrated in FIG. 4, the channel layer 140 may be formed in an annular shape surrounding the internal channel-filled insulating layer 147. In the plate layer 101, the channel layer 140 may be exposed from the channel dielectric layer 145 to contact the plate layer 101, and may be electrically connected to the plate layer 101. The channel layer 140 may include a semiconductor material such as polycrystalline silicon or single-crystalline silicon.

The channel dielectric layer 145 may be disposed between the gate electrodes 130 and the channel layer 140. Although not specifically illustrated, the channel dielectric layer 145 may include a tunneling layer, a charge storage layer, and a blocking layer sequentially stacked from the channel layer 140. The tunneling layer may tunnel charges into the charge storage layer, and may include, for example, silicon oxide (SiO₂), silicon nitride (Si₃N₄), silicon oxynitride (SiON), or combinations thereof. The charge storage layer may be a charge trap layer or a floating gate conductive layer. The blocking layer may include silicon oxide (SiO₂), silicon nitride (Si₃N₄), silicon oxynitride (SiON), a high-K dielectric material, or combinations thereof. In example embodiments, at least a portion of the channel dielectric layer 145 may extend horizontally in the gate electrodes 130. The channel pad 149 may be disposed only in an upper end of the fourth channel portion CH4 on the upper portion. The channel pad 149 may include, for example, doped polycrystalline silicon.

The gate separation regions MS may be disposed to extend in the X-direction by penetrating through the gate electrodes 130. As illustrated in FIG. 1, the gate separation regions MS may be disposed in parallel with each other. However, the arrangement shape, the number, and the like, of the gate separation regions MS are not limited to those illustrated in FIG. 1. For example, in some example embodiments, the gate separation regions MS may be further disposed in a discontinuous manner in the first to third regions R1, R2 and R3.

As illustrated in FIG. 2B, the gate separation regions MS may be connected to the plate layer 101 by penetrating through the gate electrodes 130 stacked on the plate layer 101. The gate separation regions MS may have a shape in which a width thereof decreases toward the plate layer 101 due to the high aspect ratio. The gate separation regions MS may have bent portions corresponding to those of the first and fourth channel portions CH1, CH2, CH3 and CH4. Although not specifically illustrated in FIG. 1, the gate separation regions MS may have protrusions on side surfaces thereof in the Y-direction in a plan view. The gate separation regions MS may include an insulating material, and may include, for example, silicon oxide, silicon nitride, or silicon oxynitride.

First upper separation regions SS1 may extend in the X-direction between a pair of gate separation regions MS, as illustrated in FIG. 1. The first upper separation regions SS1 may be disposed in the first and second regions R1 and R2. The first upper separation regions SS1 may penetrate through the upper gate electrodes 130U, among the gate electrodes 130. As illustrated in FIG. 1, the first upper separation regions SS1 may divide each of the upper gate electrodes 130U into four layers in the Y-direction between the pair of gate separation regions MS. However, in example embodiments, the number of first upper separation regions SS1 disposed between the pair of gate separation regions MS may be variously changed.

As illustrated in FIG. 1, the first upper separation regions SS1 may be disposed to partially cut portions of the channel structures CH. The first upper separation regions SS1 may extend to partially penetrate through portions of the channel structures CH, and thus may also contact the channel layer 140. In example embodiments, a relative arrangement of the first upper separation regions SS1 and the channel structures CH partially penetrated by the first upper separation regions SS1 on the plan view of FIG. 1 may be variously changed.

As illustrated in FIG. 1, a second upper separation region SS2 may be connected to ends of the first upper separation regions SS1 in a boundary region between the second region R2 and the third region R3, and may extend in the Y-direction. The second upper separation region SS2 may be disposed on the same level as the first upper separation regions SS1 and may have the same depth. As used herein, the terms “level” and/or “depth” may refer to a height or distance in a Z-direction (e.g., a vertical direction) from the plate layer 101 (e.g., from an upper surface of the plate layer 101). As used herein, “an element A has a greater depth than an element B” (or similar language) may mean that a distance between the element A and the plate layer 101 (e.g., in the Z-direction) is less than a distance between the element B and the plate layer 101 (e.g., in the Z-direction). A width of the second upper separation region SS2 may be identical to or different from the width of the first upper separation regions SS1. By the first and second upper separation regions SS1 and SS2, each of the upper gate electrodes 130U may be divided into a plurality of electrodes to receive separate electrical signals.

The first and second upper separation regions SS1 and SS2 may include an insulating material, and may be include, for example, silicon oxide, silicon nitride, or silicon oxynitride.

The first and second contact plugs MC1 and MC2 may be physically and electrically connected to the gate electrodes 130. The first contact plugs MC1 may be connected to the upper gate electrodes 130U in the second region R2 adjacent to the first region R1. The second contact plugs MC2 may be connected to the memory gate electrodes 130M and the lower gate electrodes 130L in the third region R3 outside the second region R2. In this specification, the terms “first contact plug” and “second contact plug” may refer to any contact plug of the first and second contact plugs MC1 and MC2 in the claims, unlike in the detailed description.

The first contact plugs MC1 may be disposed between the first upper separation regions SS1 adjacent in the Y-direction and between the first upper separation region SS1 and the gate separation region MS adjacent in the Y-direction, in plan view. The second contact plugs MC2 may be disposed between adjacent gate separation regions MS in the Y-direction. Each of the first and second contact plugs MC1 and MC2 may be disposed in a zigzag form in plan view, but are not limited thereto. The second contact plugs MC2 may be disposed in a different pattern and/or a different separation distance from the first contact plugs MC1. The second contact plugs MC2 may have an identical or different diameter to or from the first contact plugs MC1. For example, diameters of the first and second contact plugs MC1 and MC2 may be in a range of about 350 nanometers (nm) to 550 nm.

The number of first contact plugs MC1 disposed between the first upper separation regions SS1 adjacent to each other in the Y-direction and between the first upper separation regions SS1 and the gate separation regions MS adjacent to each other in the Y-direction, respectively, may be equal to or greater than the number of upper gate electrodes 130U stacked in the Z-direction. The number of second contact plugs MC2 disposed between the gate separation regions MS adjacent to each other in the Y-direction may be equal to or greater than the number of memory gate electrodes 130M and lower gate electrodes 130L stacked in the Z-direction.

The first and second contact plugs MC1 and MC2 may extend in the Z-direction only to the gate electrode 130 electrically connected from the upper portion. The first contact plugs MC1 may be connected to the upper gate electrode 130U by penetrating through at least one of the upper gate electrodes 130U except the first contact plugs MC1 connected to an upper gate electrode 130U in an uppermost portion. The second contact plugs MC2 may penetrate through the entire upper gate electrodes 130U and may be connected to the memory gate electrodes 130M and the lower gate electrodes 130L. The first and second contact plugs MC1 and MC2 may be electrically separated from the penetrating gate electrodes 130 by at least the contact spacers 160. The first and second contact plugs MC1 and MC2 may be connected to the gate electrodes 130 by partially recessing the gate electrodes 130 from upper surfaces thereof. However, a depth at which the first and second contact plugs MC1 and MC2 recess the gate electrodes 130 may be variously changed in example embodiments.

The first and second contact plugs MC1 and MC2 may include a conductive material, for example, at least one of tungsten (W), copper (Cu), aluminum (Al), or alloys thereof. In some example embodiments, each of the first and second contact plugs MC1 and MC2 may include a barrier layer forming a lower surface and a side surface thereof, and the barrier layer may include a conductive material, for example, tungsten nitride (WN), tantalum nitride (TaN), titanium nitride (TiN), or a combination thereof.

The contact spacers 160 may be respectively disposed on side surfaces of the first and second contact plugs MC1 and MC2. The contact spacers 160 may electrically separate the first and second contact plugs MC1 and MC2 from the gate electrodes 130 through which the first and second contact plugs MC1 and MC2 penetrate. The contact spacers 160 may extend onto upper surfaces of the gate electrodes 130 connected to the first and second contact plugs MC1 and MC2. The contact spacers 160 may expose lower surfaces of the first and second contact plugs MC1 and MC2. Lower ends of the contact spacers 160 may be disposed on a level higher than a level of lower ends of the first and second contact plugs MC1 and MC2, but the present disclosure is not limited thereto.

The contact spacers 160 may include an insulating material, and may include, for example, silicon oxide, silicon nitride, or silicon oxynitride. In some example embodiments, the contact spacers 160 may include an insulating material different from the contact liner layers 150. In some example embodiments, the contact spacers 160 may include a plurality of layers. For example, the contact spacer 160 may include a silicon oxide layer in an external side and a silicon nitride layer in an internal side.

The contact liner layers 150 may be respectively disposed on the side surfaces of the first and second contact plugs MC1 and MC2, and may be disposed on external surfaces (i.e., outer side surfaces) of the contact spacers 160. The contact spacers 160 may be respectively interposed between the first and second contact plugs MC1 and MC2 and the contact liner layers 150. The contact liner layers 150 may be disposed on the side surfaces of the first and second contact plugs MC1 and MC2 and the external surfaces of the contact spacers 160 in upper regions of the first and second contact plugs MC1 and MC2.

The contact liner layers 150 may expose lower regions of the first and second contact plugs MC1 and MC2 and lower regions of the contact spacers 160. A lower end of the contact liner layer 150 may be disposed on a level higher than a level of lower ends of corresponding first and second contact plugs MC1 and MC2 and a lower end of the contact spacer 160. In at least portions of the contact liner layers 150, a length of the first and second contact plugs MC1 and MC2 exposed by the contact liner layer 150 may be greater than the length of the contact liner layer 150. For example, at least one contact liner layer 150 may extend a first length in the Z-direction on a side surface of a corresponding first or second contact plug MC1 or MC2, the first or second contact plug MC1 or MC2 may extend a second length in the Z-direction, and the second length may be at least twice the first length. On side surfaces of each of the first and second contact plugs MC1 and MC2, a length of the contact liner layer 150 in the Z-direction may be less than a length of the contact spacer 160 in the Z-direction.

The contact liner layers 150 may have different lengths (or heights) and different shapes on some side surfaces of the first and second contact plugs MC1 and MC2 extending by different depths, and may have the same shape on the other side surfaces thereof. For example, the contact liner layers 150 may have the same shape on a first second contact plug MC2 and a fifth second contact plug MC2 from the left side of FIG. 2A having different depths. The contact liner layers 150 may have the same shape on the side surfaces of the first and second contact plugs MC1 and MC2 extending by the same depth.

Lengths of the contact liner layers 150 in the Z-direction may not be proportional to the depths of the corresponding first and second contact plugs MC1 and MC2. For example, as illustrated in FIG. 2A, when a contact liner layer 150 on side surfaces of the first and second contact plugs MC1 and MC2 having a first depth is compared to a contact liner layer 150 on side surfaces of the first and second contact plugs MC1 and MC2 having a second depth greater than the first depth, the former contact liner layer 150 may be longer, or the latter contact liner layer 150 may be longer. For example, at least one contact liner layer 150 on a corresponding first or second contact plug MC1 or MC2 having a first depth may extend a greater length in the Z-direction than at least one other contact liner layer 150 on a corresponding first or second contact plug MC1 or MC2 having a second depth that is greater than the first depth (e.g., see the contact liner layers 150 respectively on a second first contact plug MC1 and a first second contact plug MC2 from the left side of FIG. 2A compared to the contact liner layer 150 on a second contact plug MC2 from the left side of FIG. 2A).

Some of the contact liner layers 150, which are the first contact liner layers, may have a substantially constant thickness, and the others of the contact liner layers 150, which are the second contact liner layers, may include a plurality of regions having a thickness that decreases toward the plate layer 101 in the Z-direction. In this specification, a thickness of the contact liner layers 150 may denote a thickness in the X-direction and/or the Y-direction, perpendicular to the Z-direction, which is an extension direction of the contact liner layers 150.

The first contact liner layers and the second contact liner layers may be disposed on the first and second contact plugs MC1 and MC2 having different depths. For example, the first contact liner layers may be disposed on the side surfaces of the first and second contact plugs MC1 and MC2 connected to 2ⁿ (where n=0, 1, 2, . . . )th gate electrodes 130 from an upper portion, among the gate electrodes 130. The second contact liner layers may be disposed on side surfaces of the first and second contact plugs MC1 and MC2 connected to the other gate electrodes 130.

For the second contact liner layers having regions of different thicknesses, the thickness may be discontinuously changed between the regions. In other words, for the second contact liner layers having regions of different thicknesses, the thickness of each second contact liner layer may not continuously change (i.e., may not gradually change) but rather may discontinuously change in distinct steps between the regions. Internal surfaces (i.e., inner side surfaces) of the regions may be coplanar with each other, and there may be a bent portion or a step portion between external surfaces (i.e., external side surfaces) of the regions according to a change in thickness. For example, for the second contact liner layers having regions of different thicknesses, each second contact liner layer may have a step portion on an outer side surface thereof between adjacent ones of the regions. In other words, inner side surfaces of the regions may be collinear with each other (e.g., in the Z-direction), and a bent portion or a step portion may be between outer side surfaces of the regions (e.g., due to a change in thickness). However, in some example embodiments, the bent portion or the step portion may not be clearly recognized. The number of the regions may be, for example, in the range of two to ten.

As illustrated in FIG. 3, on a side surface of a contact plug MC1_1 connected to the uppermost upper gate electrode 130U, a contact liner layer 150_1 may have a substantially uniform thickness, which is a first thickness T1. The first thickness T1 in the contact liner layer 150_1 may be at least a maximum thickness. In other words, the first thickness T1 may be a maximum thickness of the contact liner layer 150_1. A lower end of the contact liner layer 150_1 may be spaced apart from an upper surface of the uppermost upper gate electrode 130U in the Z-direction.

On a side surface of a second contact plug MC2_5 connected to a fifth gate electrode 130 (130M) from the upper portion, among the gate electrodes 130, a contact liner layer 150_5 may have a second thickness T2 greater than the first thickness T1 in an upper region, and may have the first thickness T1 in a lower region therebelow. The second thickness T2 may be, for example, twice as thick as (i.e., two times greater than) the first thickness T1. For example, an inner side surface of the lower region of the contact liner layer 150_5 and an inner side surface of the upper region of the contact liner layer 150_5 may be collinear with each other (e.g., in the Z-direction), and a step portion may be between an outer side surface of the lower region of the contact liner layer 150_5 and an outer side surface of the upper region of the contact liner layer 150_5 (e.g., due to a change from the first thickness T1 to the second thickness T2). The upper region may be disposed on a level higher than a level of the upper surface of the uppermost upper gate electrode 130U. For example, a first distance between the upper region and the upper surface of the plate layer 101 (e.g., in the Z-direction) may be greater than a second distance between the upper surface of the uppermost upper gate electrode 130U and the upper surface of the plate layer 101 (e.g., in the Z-direction). A level of a lower end of the upper region may be substantially the same as a level of a lower portion of the contact liner layer 150_1. In some example embodiments, the lower region may be a region in contact with the upper surface of the uppermost upper gate electrode 130U.

On a side surface of a second contact plug MC2_23 connected to a twenty-third gate electrode 130 (130L) from the upper portion, among the gate electrodes 130, a contact liner layer 150_23 may have a fourth thickness T4 in the upper region, may have a third thickness T3 less than the fourth thickness T4 in a first intermediate region therebelow, may have the second thickness T2 less than the third thickness T3 in a second intermediate region therebelow, and may have the first thickness T1 in a lower region therebelow. The third thickness T3 may be, for example, three times greater than the first thickness T1, and the fourth thickness T4 may be, for example, four times greater than the first thickness T1. For example, an inner side surface of the lower region of the contact liner layer 150_23, an inner side surface of the second intermediate region of the contact liner layer 150_23, an inner side surface of the first intermediate region of the contact liner layer 150_23, and an inner side surface of the upper region of the contact liner layer 150_23 may be collinear with each other (e.g., in the Z-direction). A first step portion may be between an outer side surface of the lower region of the contact liner layer 150_23 and an outer side surface of the second intermediate region of the contact liner layer 150_23 (e.g., due to a change from the first thickness T1 to the second thickness T2), a second step portion may be between an outer side surface of the second intermediate region of the contact liner layer 150_23 and an outer side surface of the first intermediate region of the contact liner layer 150_23 (e.g., due to a change from the second thickness T2 to the third thickness T3), and a third step portion may be between an outer side surface of the first intermediate region of the contact liner layer 150_23 and an outer side surface of the upper region of the contact liner layer 150_23 (e.g., due to a change from the third thickness T3 to the fourth thickness T4). A level of a lower end of the upper region may be substantially the same as a level of a lower end of the contact liner layer 150_1. The first intermediate region may be a region that contacts or is adjacent to one gate electrode 130, that is, the uppermost upper gate electrode 130U. The second intermediate region may be a region horizontally overlapping two gate electrodes 130 (e.g., two upper gate electrodes 130U). The lower region may be a region horizontally overlapping four gate electrodes 130 (e.g., one upper gate electrode 130U and three memory gate electrodes 130M).

In the three contact liner layers 150_1, 150_5 and 150_23, levels of the regions having the first thickness T1 may be different from each other. In other words, in the three contact liner layers 150_1, 150_5 and 150_23, the regions having the first thickness T1 may be spaced apart from the plate layer 101 (e.g., from an upper surface of the plate layer 101) by different distances in the Z-direction. For example, a region of the contact liner layer 150_1 having the first thickness T1 may be spaced apart from the plate layer 101 (e.g., from an upper surface of the plate layer 101) by the same distance in the Z-direction as a region of the contact liner layer 150_5 having the second thickness T2 and a region of the contact liner layer 150_23 having the fourth thickness T4. In the two contact liner layers 150_5 and 150_23, levels of the regions having the second thickness T2 may be different from each other.

A thickness of the contact liner layer 150 may be changed on the uppermost upper gate electrode 130U, for example, as in the contact liner layers 150_5 and 150_23 of FIG. 3, and may be further changed after the first and second contact plugs MC1 and MC2 penetrate through 2ⁿ (where n=0, 1, 2, . . . ) gate electrodes 130 from the upper portion. When the contact liner layer 150 is disposed on a side surface of the first contact plug connected to an Nth (where N is a natural number) gate electrode 130 from the uppermost portion, among the gate electrodes 130, the number of regions having different thicknesses in the contact liner layer 150 may be equal to or proportional to a sum of the numbers of each digit when N is expressed in binary, but the present disclosure is not limited thereto.

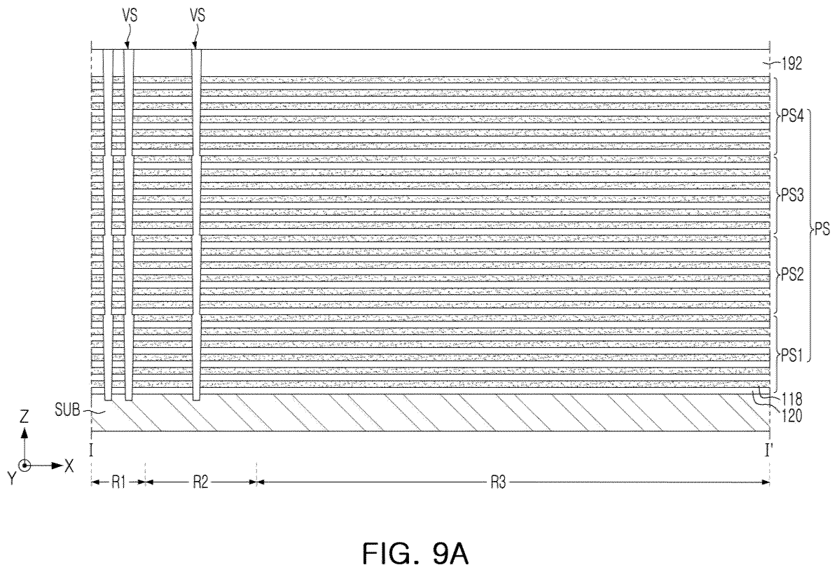

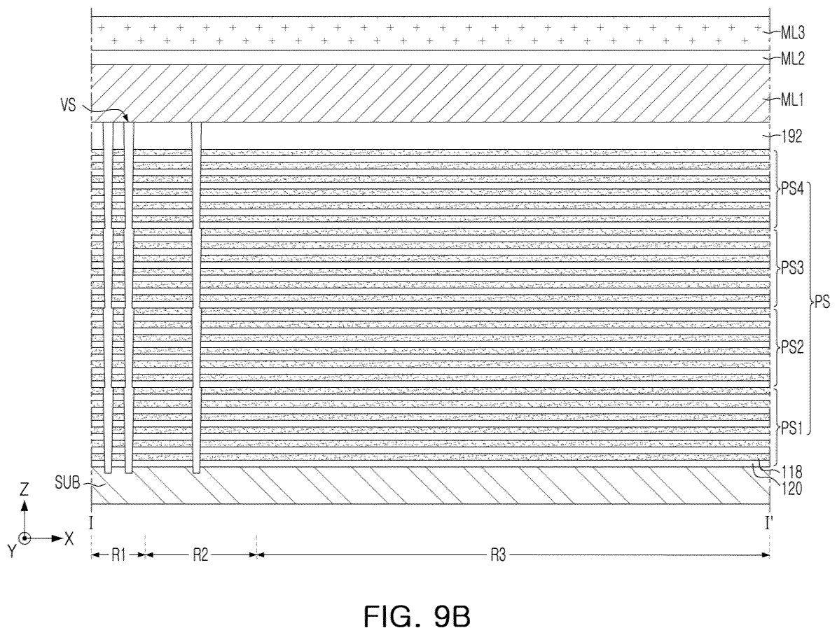

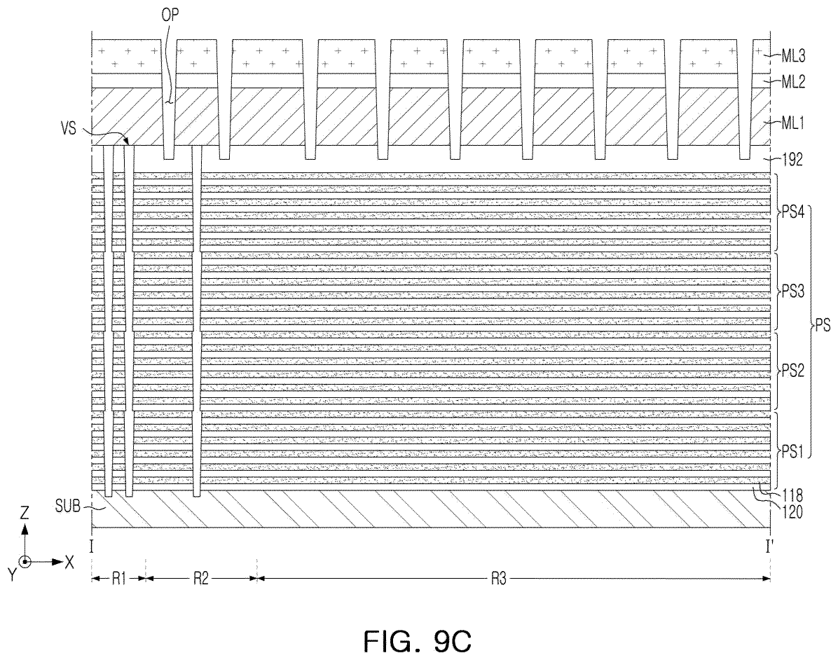

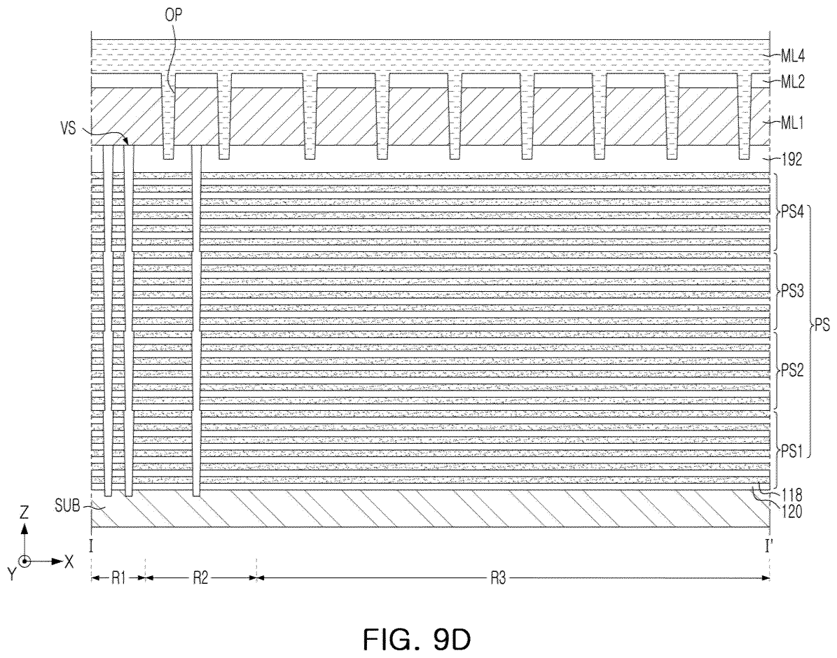

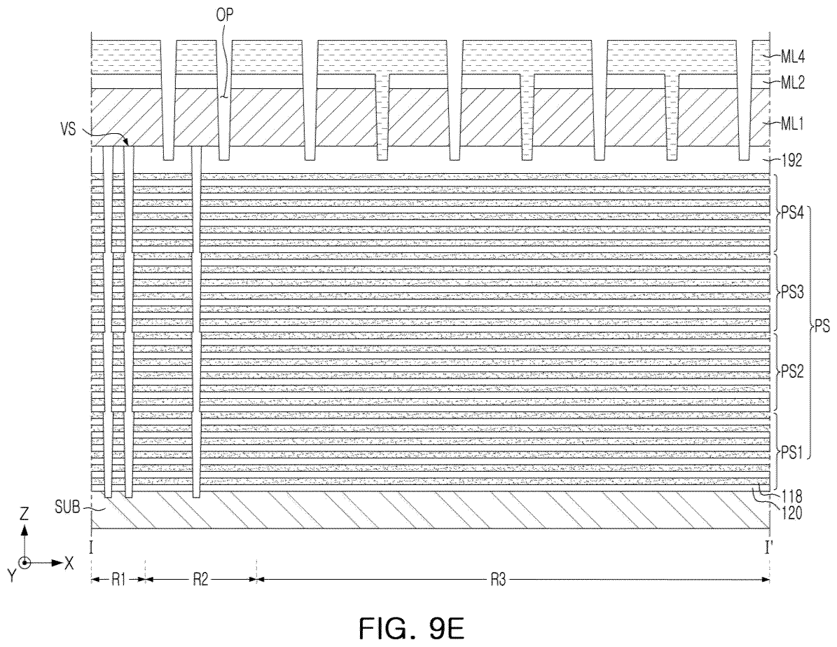

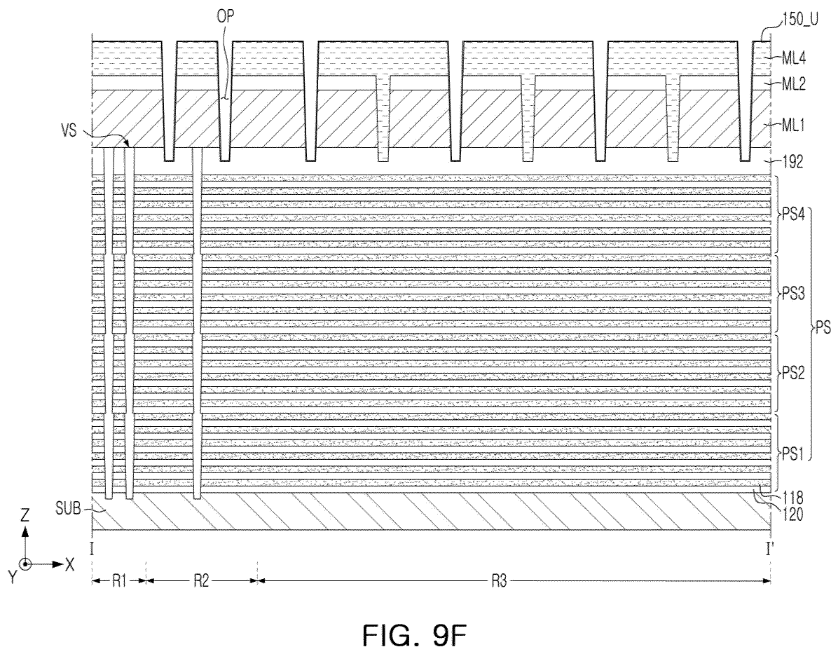

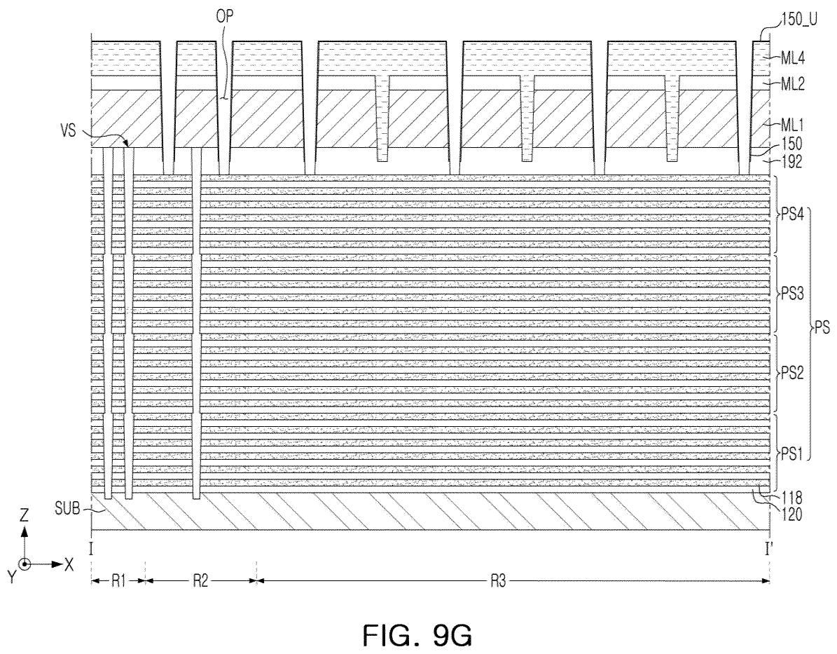

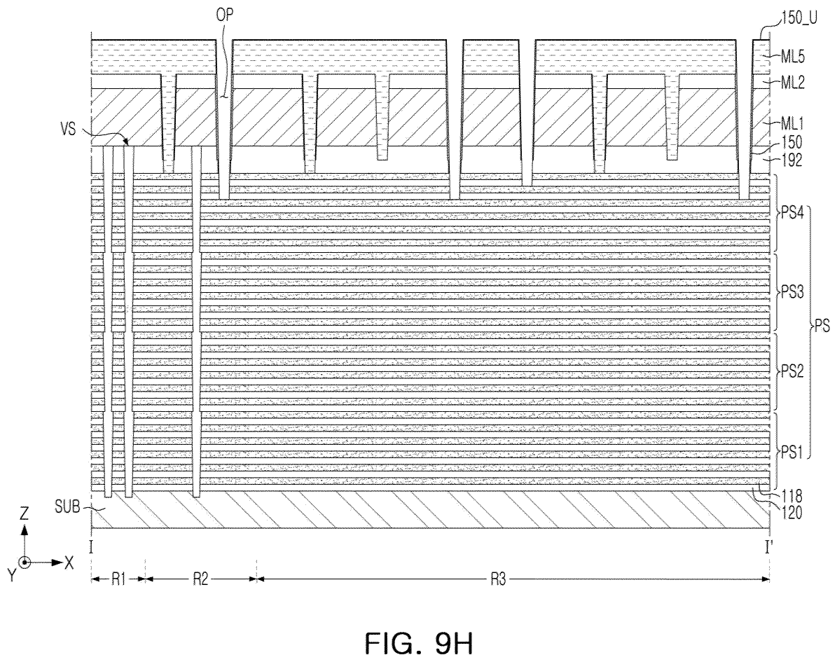

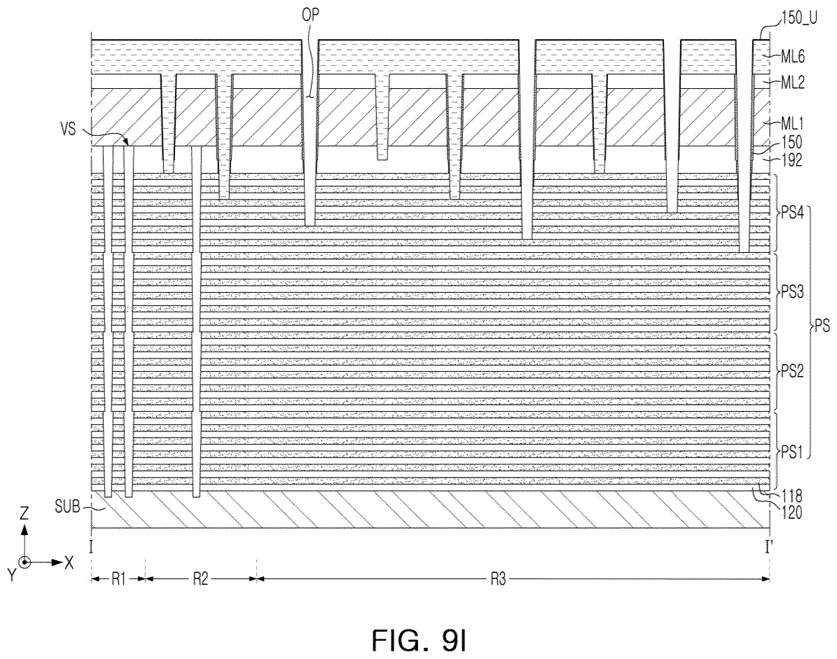

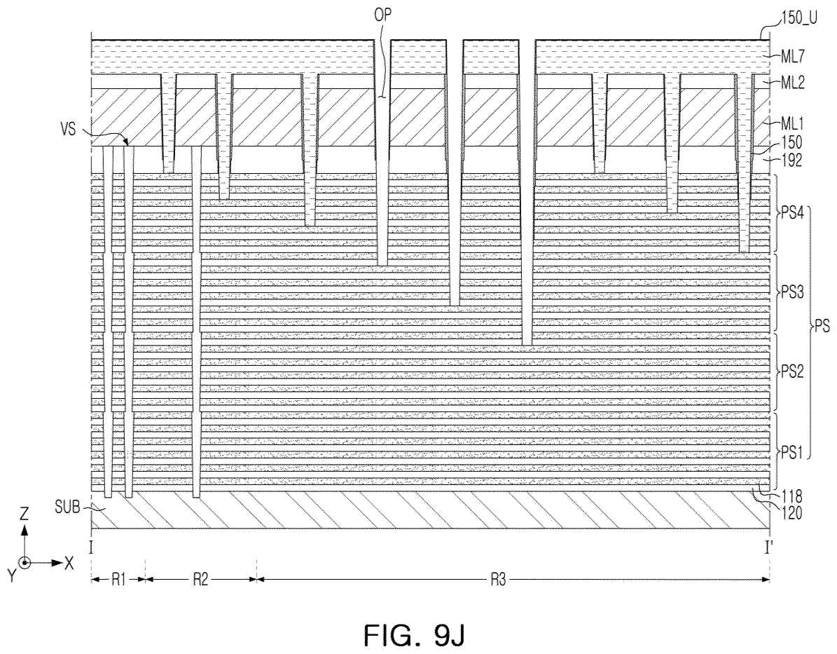

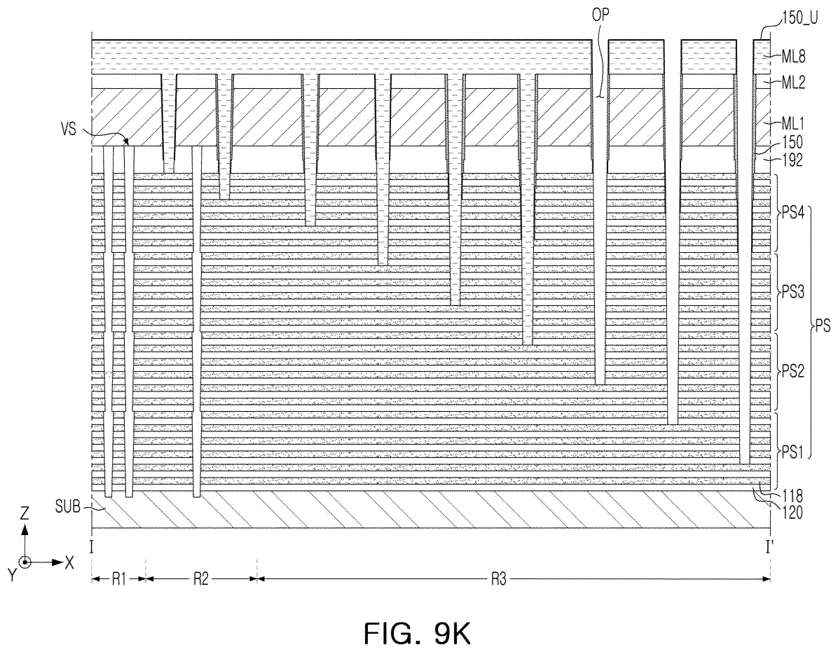

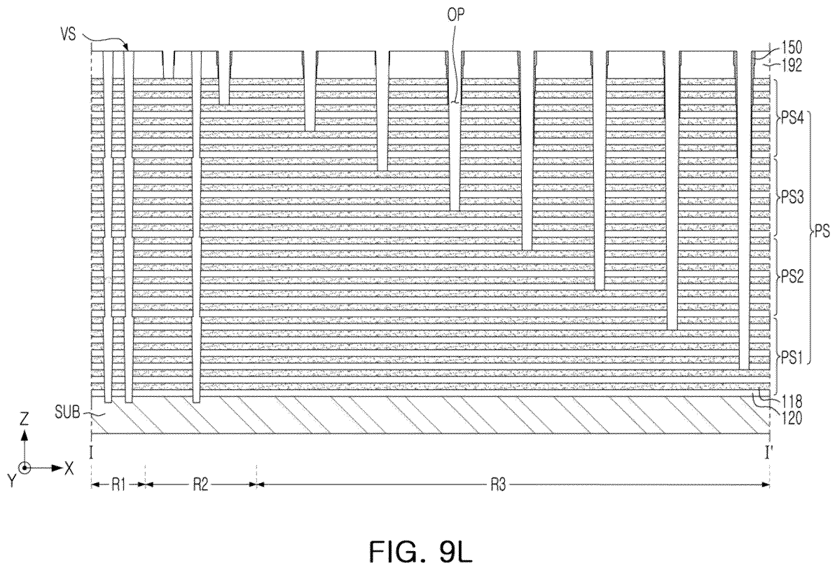

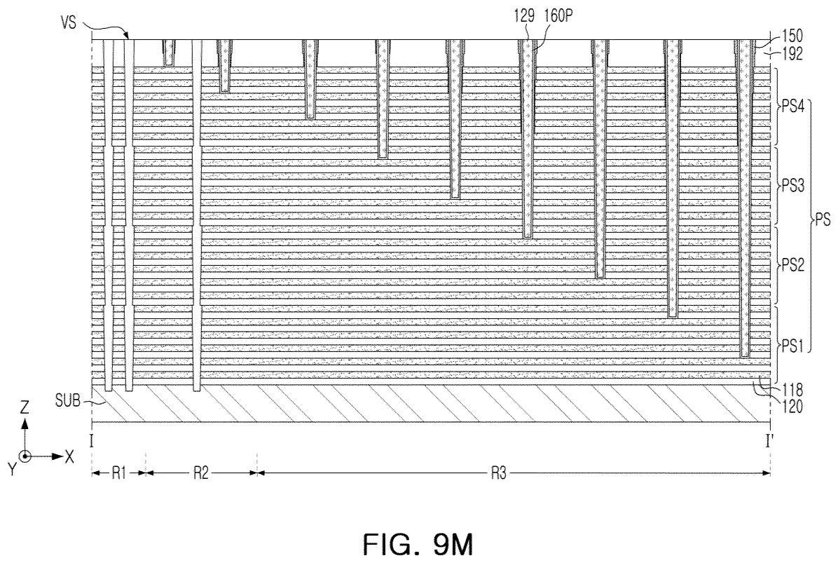

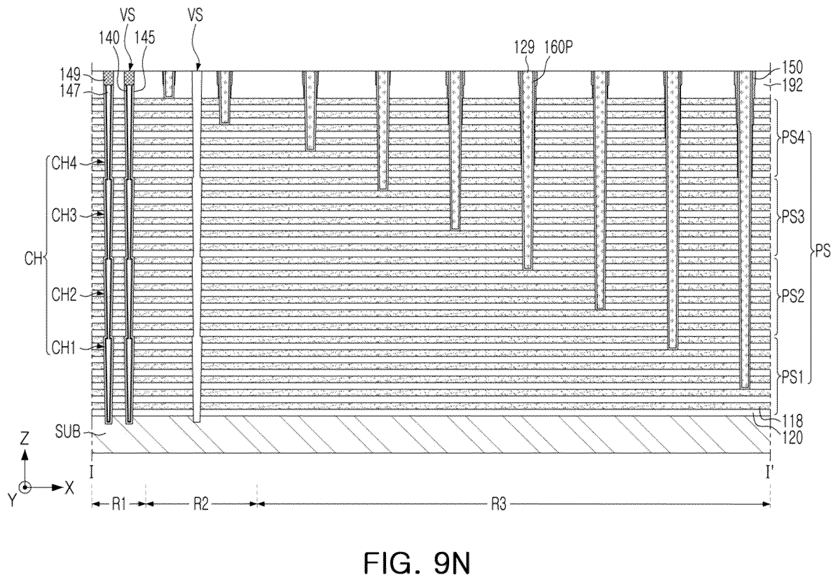

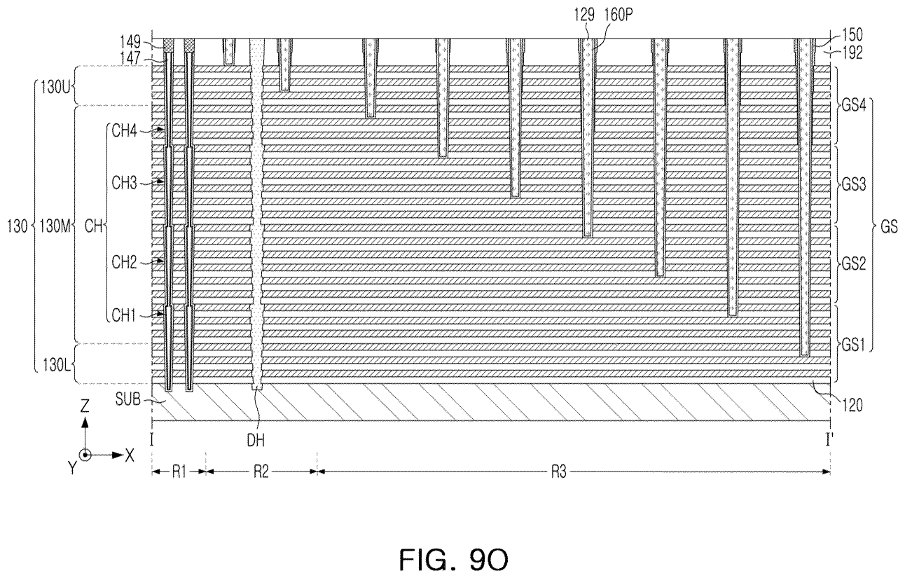

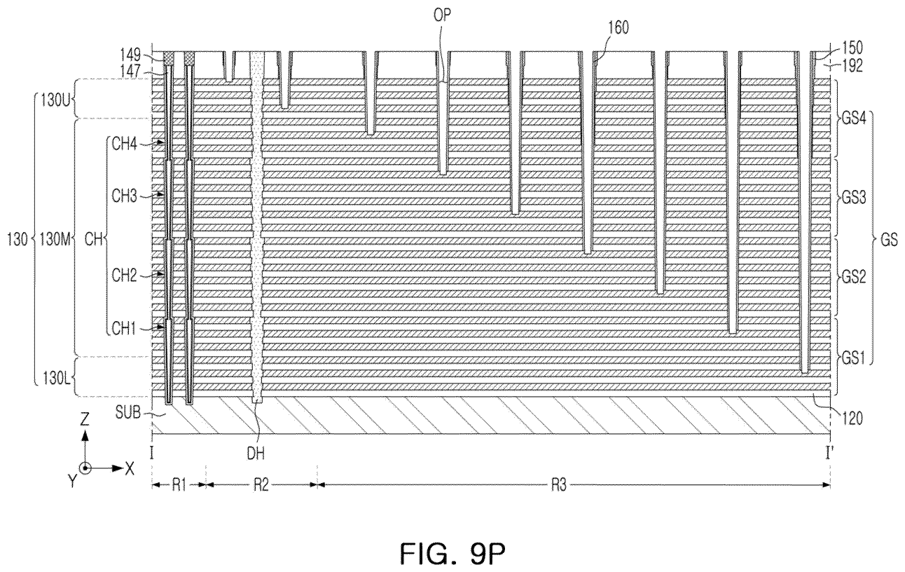

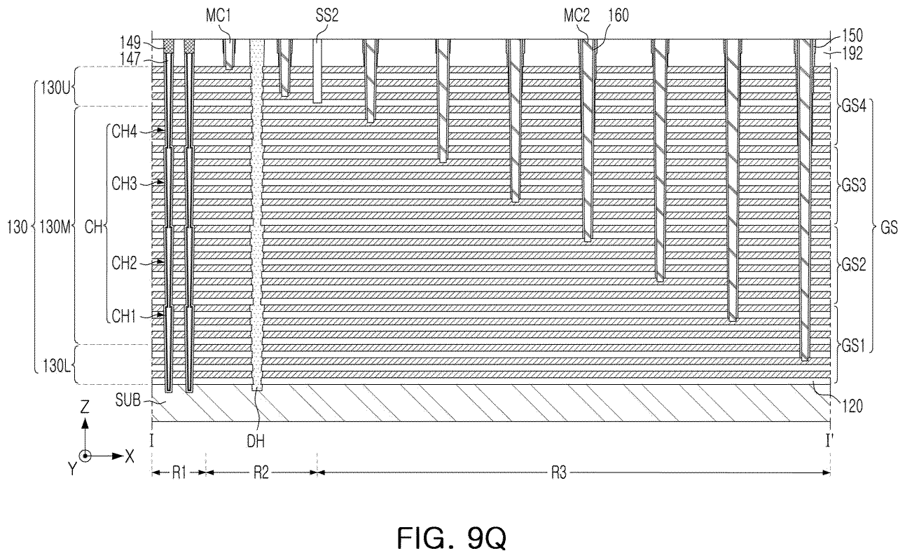

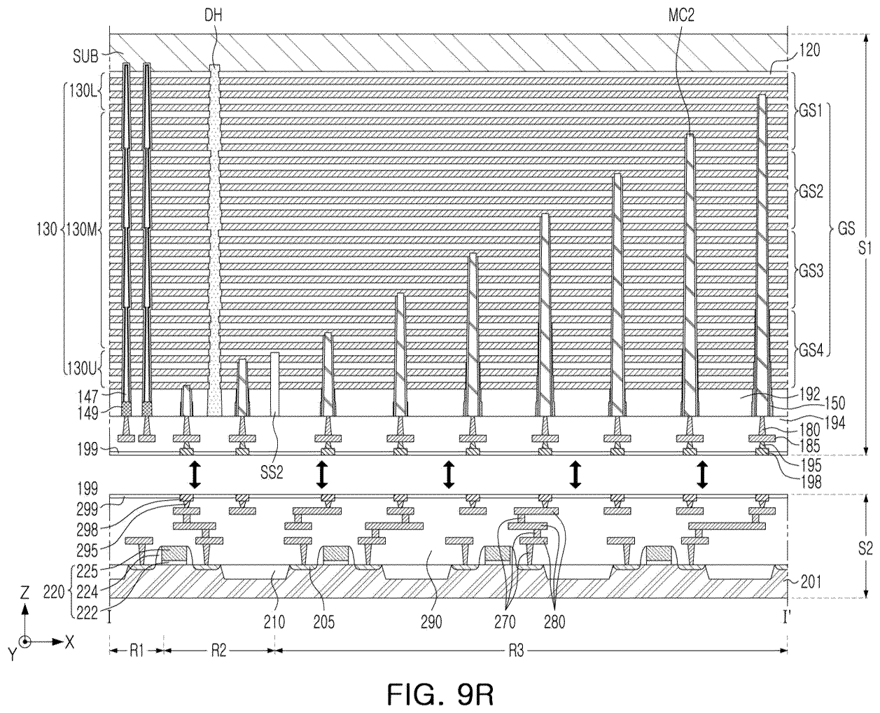

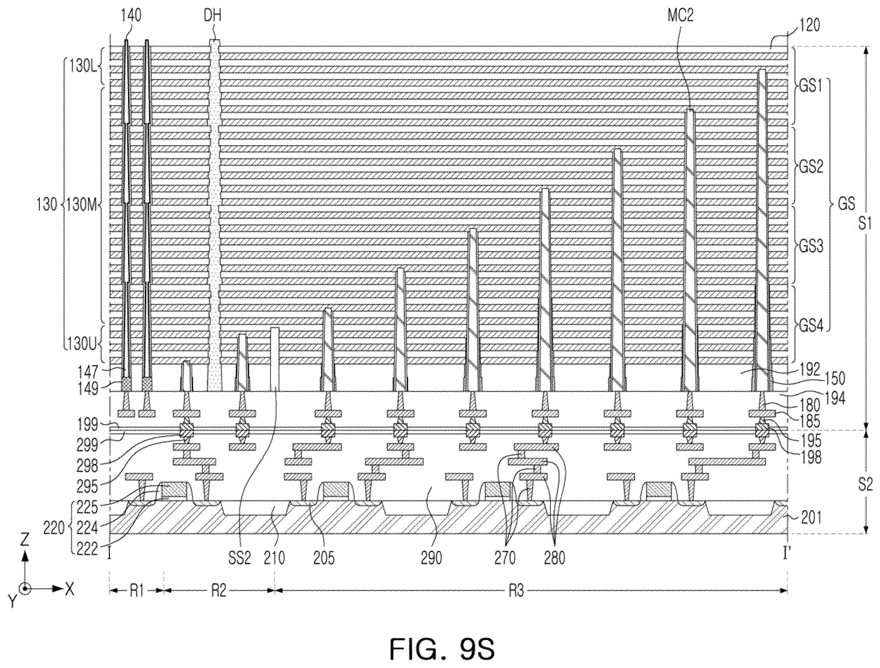

The different shapes of the contact liner layers 150 may be due to a formation process of the contact holes in which the first and second contact plugs MC1 and MC2 are disposed. For example, the contact liner layer 150 may have a constant thickness in a region formed by a single etching process, and the contact liner layers 150 may have different thicknesses in regions formed by different etching processes. Additionally, the contact liner layer 150 may not be disposed in a region formed by a last etching process in each contact hole. This will be described in more detail with reference to FIGS. 9B to 9K below.

The contact liner layers 150 may include an insulating material, for example, at least one of SiO, SiCN, SiOC, SiON, or SiOCN. In some example embodiments, the contact liner layers 150 may include the same material as at least a portion of the contact spacers 160. For example, the contact liner layer 150 may include silicon oxide, and the contact spacer 160 may include a silicon oxide layer in an external side and a silicon nitride layer in an internal side. In this case, an interface between the contact liner layer 150 and the contact spacer 160 may not be distinguished.

The dummy vertical structures DH may be spaced apart from each other in rows and columns on the plate layer 101 in the second and third regions R2 and R3. As illustrated in FIG. 1, the dummy vertical structures DH may be disposed in a zigzag shape with the first and second contact plugs MC1 and MC2 in plan view. The dummy vertical structures DH may be arranged in different patterns in the second region R2 and the third region R3, but the present disclosure is not limited thereto. In some example embodiments, portions of the dummy vertical structures DH may be in contact with the first and second contact plugs MC1 and MC2.

The dummy vertical structures DH may have a circular shape, an oval shape, or a shape similar thereto in plan view. The dummy vertical structures DH have a pillar shape penetrating through the gate electrodes 130 and may have inclined side surfaces that become narrower as the dummy vertical structures DH move closer to the plate layer 101 depending on the aspect ratio. A diameter of the dummy vertical structures DH may be greater than a diameter of the channel structures CH, but the present disclosure is not limited thereto. The dummy vertical structures DH may include regions protruding from side surfaces thereof toward the gate electrodes 130. The dummy vertical structures DH may have bent portions corresponding to those of the first to fourth channel portions CH1, CH2, CH3 and CH4. The dummy vertical structures DH may not include a conductive material and may include an insulating material. The dummy vertical structures DH may include, for example, silicon oxide, silicon nitride, or silicon oxynitride.

The first cell region insulating layer 192 may be disposed on (e.g., to cover and/or overlap) the gate structure GS. The second cell region insulating layer 194 may be disposed on the first cell region insulating layer 192. Each of the first and second cell region insulating layers 192 and 194 may include a plurality of insulating layers according to example embodiments. The first and second cell region insulating layers 192 and 194 may be formed of an insulating material, and may include, for example, at least one of silicon oxide, silicon nitride, or silicon oxynitride.

The studs 180 and the cell interconnection lines 185 may be included in a cell interconnection structure electrically connected to the memory cells. The studs 180 may penetrate through a portion of the second cell region insulating layer 194 and may be connected to the channel structures CH and the first and second contact plugs MC1 and MC2, and may be electrically connected to the channel layers 140 and the gate electrodes 130. The studs 180 may have a plug shape, and the cell interconnection lines 185 may have a line shape, but the present disclosure is not limited thereto. The studs 180 and the cell interconnection lines 185 may include a metal, for example, tungsten (W), copper (Cu), and/or aluminum (Al).

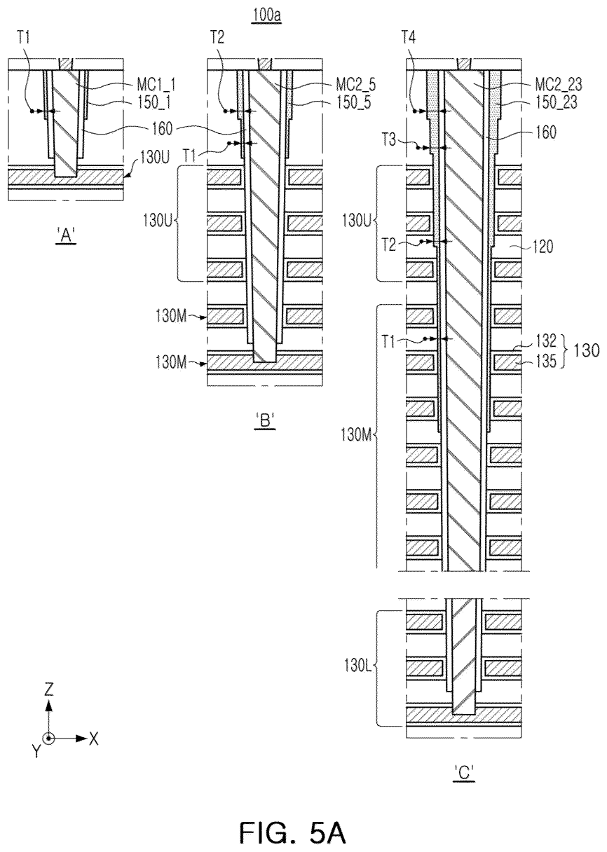

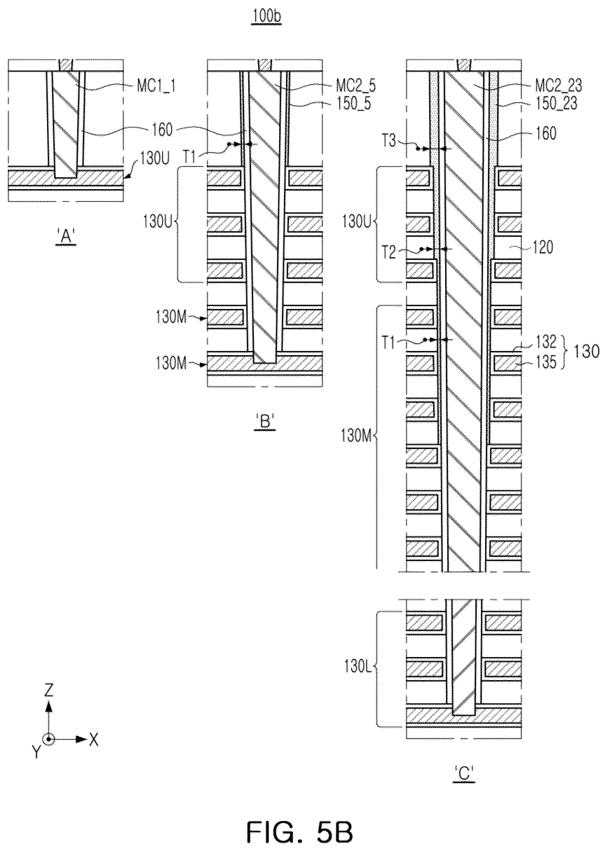

FIGS. 5A and 5B are partially enlarged views of a semiconductor device according to example embodiments. Each of FIGS. 5A and 5B illustrates regions corresponding to FIG. 3.

Referring to FIG. 5A, in a semiconductor device 100a, levels of lower ends of the contact liner layers 150_1, 150_5 and 150_23 and levels of lower ends of the contact spacers 160 may be different from those in the example embodiment of FIG. 3.

The lower end of the contact spacer 160 may be spaced apart from an upper surface of the gate electrode 130 connected to the corresponding first and second contact plugs MC1 and MC2, and may thus be disposed in the interlayer insulating layer 120 in the Z-direction. In some example embodiments, the lower end of the contact spacer 160 may be disposed on the same level as a level of a lower surface of the gate electrode 130 on the gate electrode 130 connected to the corresponding first and second contact plugs MC1 and MC2.

The lower ends of the contact liner layers 150_5 and 150_23 may also not contact an upper surface of a gate electrode 130 adjacent thereto, and may be spaced apart from the upper surface of the gate electrode 130 in the Z-direction. Additionally, points at which a thickness of the contact liner layers 150_23 changes may also horizontally overlap the interlayer insulating layers 120.

Levels of lower ends of the contact liner layers 150_1, 150_5 and 150_23 and levels of the lower ends of the contact spacers 160 may be changed depending on an etching depth during a manufacturing process of the semiconductor device 100a.

Referring to FIG. 5B, in a semiconductor device 100b, the contact liner layers 150_5 and 150_23 may not include a region in which a thickness thereof is changed on the uppermost upper gate electrode 130U. Accordingly, the contact liner layer 150_1 (see FIG. 3) may be omitted on the side surface of the first contact plug MC1_1 connected to the uppermost upper gate electrode 130U. The contact liner layers 150_5 and 150_23 may extend with a constant thickness on the uppermost upper gate electrode 130U.

The shape of the contact liner layers 150_5 and 150_23 may be determined as regions including upper regions of the contact liner layers 150_1, 150_5 and 150_23 in FIG. 3 are removed during the manufacturing process.

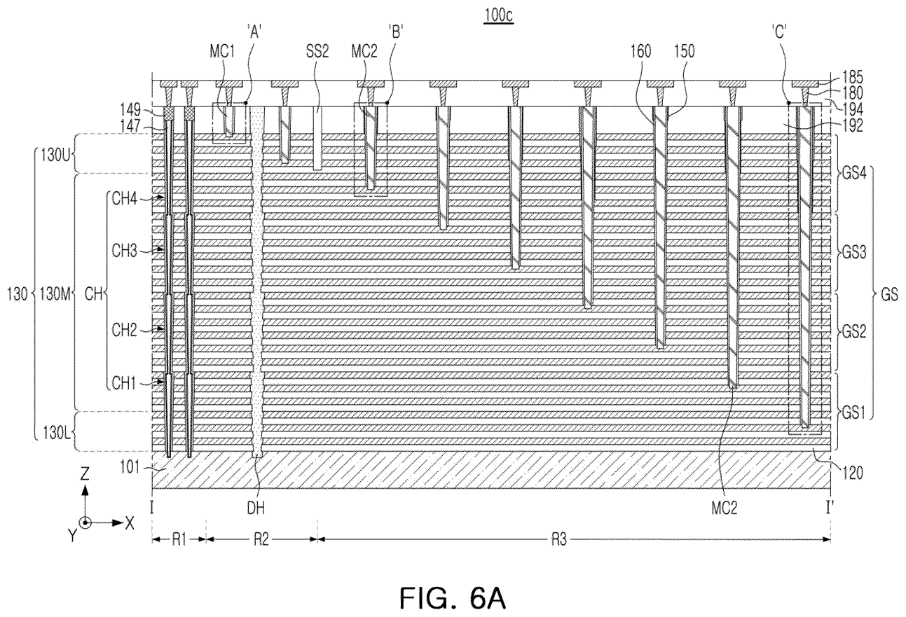

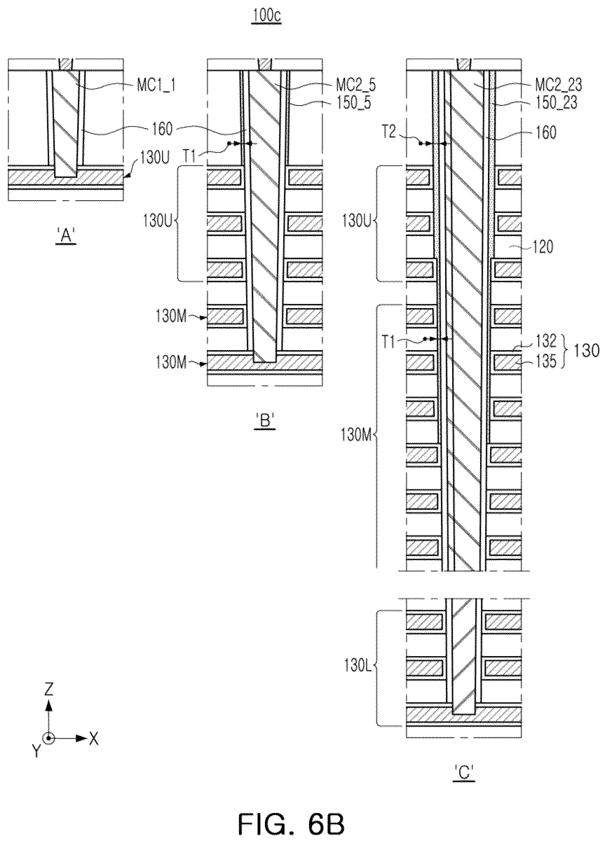

FIGS. 6A and 6B are cross-sectional views and partially enlarged views of a semiconductor device according to example embodiments. FIG. 6A illustrates a region corresponding to FIG. 2A, and FIG. 6B illustrates regions corresponding to FIG. 3.

Referring to FIGS. 6A and 6B, in a semiconductor device 100c, the contact liner layers 150 may be disposed only on some side surfaces of the first and second contact plugs MC1 and MC2, and the shape of each contact liner layer 150 may also be different from that in the example embodiments of FIGS. 2A and 3. The contact liner layers 150 may be disposed only on the side surfaces of the first and second contact plugs MC1 and MC2 disposed in contact holes formed through an etching process performed at a depth greater than a predetermined depth, among the first and second contact plugs MC1 and MC2.

For example, among the contact holes, the contact liner layers 150 may be disposed only on the side surfaces of the first and second contact plugs MC1 and MC2 formed by an etching process of etching to a depth of at least four times the sum of a thickness of the gate electrode 130 and a thickness of the interlayer insulating layer 120. This may be a structure in which a unit contact liner layer 150_U (see FIG. 9F) is formed only when the etching process with a relatively deep etching depth is performed. Accordingly, in example embodiments, the unit contact liner layer 150_U may be formed only in some of the etching processes of the contact holes, and accordingly, the arrangement position and shape of final contact liner layers 150 may also be variously changed.

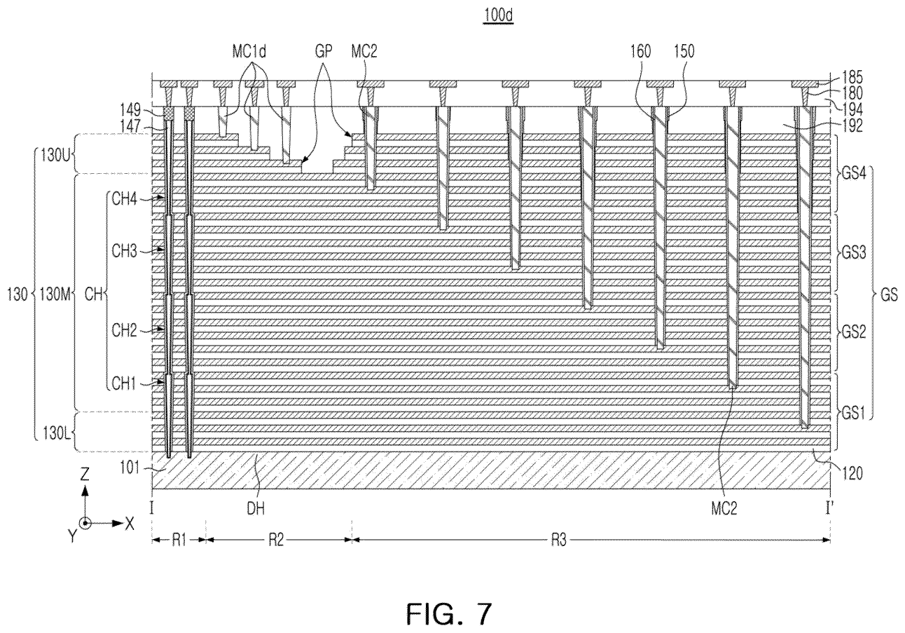

FIG. 7 is a cross-sectional view of a semiconductor device according to example embodiments. FIG. 7 illustrates a region corresponding to FIG. 2A.

Referring to FIG. 7, in a semiconductor device 100d, first contact plugs MC1d may be disposed in a form that does not penetrate through the gate electrodes 130. Additionally, the semiconductor device 100d may not include the second upper separation region SS2 of FIG. 1 and FIG. 2A.

In some example embodiments, the upper gate electrodes 130U may have a step structure GP in the second region R2. Accordingly, in the upper gate electrodes 130U, an upper gate electrode 130U in a lower portion may extend to be longer in the X-direction than the upper gate electrode 130U in an upper portion, so that an upper surface thereof may be exposed to the first cell region insulating layer 192. The upper gate electrodes 130U may be connected to the first contact plugs MC1d in the regions exposed in this manner.

The first contact plugs MC1d may be connected to the upper gate electrodes 130U by penetrating through the first cell region insulating layer 192. The contact spacers 160 and the contact liner layer 150 may not be disposed on side surfaces of the first contact plugs MC1d. In some example embodiments, the contact spacers 160 may be further disposed on the side surfaces of the first contact plugs MC1d, and the contact liner layer 150 may not be disposed thereon.

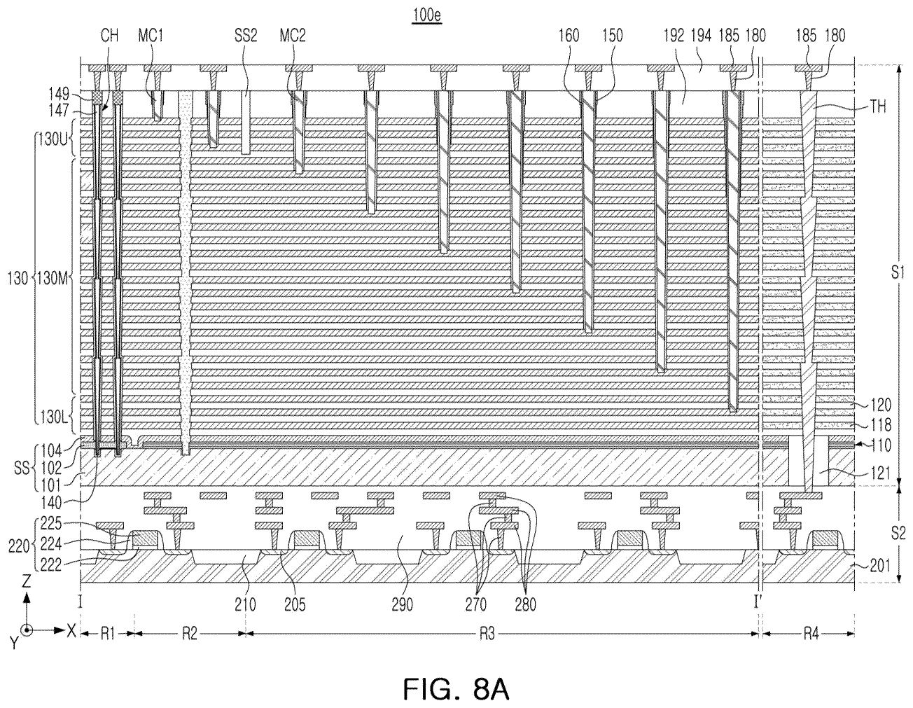

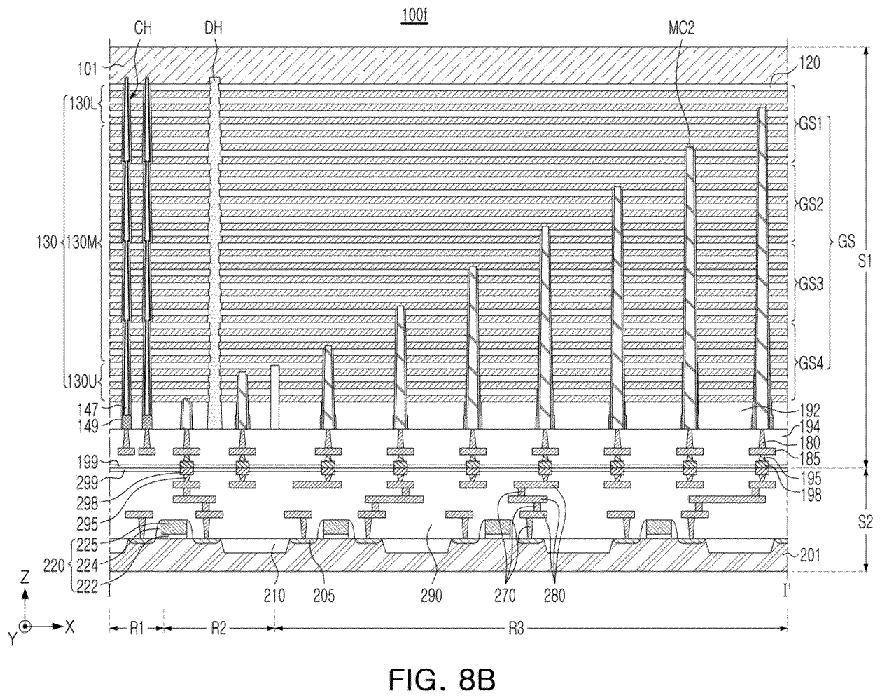

FIGS. 8A and 8B are cross-sectional views of a semiconductor device according to example embodiments. Each of FIGS. 8A and 8B illustrates a region corresponding to FIG. 2A.

Referring to FIG. 8A, a semiconductor device 100e may include a first semiconductor structure S1 and a second semiconductor structure S2 below (i.e., on a lower surface of) the first semiconductor structure S1. The first semiconductor structure S1 may include a memory cell region, and the second semiconductor structure S2 may include a peripheral circuit region. In some example embodiments, different from that illustrated, the second semiconductor structure S2 may be disposed on the first semiconductor structure S1.

The description described above with reference to FIGS. 1, 2A, 2B, 3, and 4 may be equally applied to the first semiconductor structure S1. However, the first semiconductor structure S1 may further include a fourth region R4, and may further include first and second horizontal conductive layers 102 and 104, a horizontal insulating layer 110, a substrate insulating layer 121, and a through-via TH disposed in the fourth region R4.

The fourth region R4 may be a region in which the gate electrodes 130 do not extend. In the fourth region R4, sacrificial insulating layers 118 may be alternately stacked with the interlayer insulating layers 120 on the plate layer 101. The through-via TH may extend into the second semiconductor structure S2 by penetrating through a stack structure of the sacrificial insulating layers 118 and the interlayer insulating layers 120. However, in some example embodiments, the through-via TH may be disposed to penetrate through an insulating region formed after the sacrificial insulating layers 118 are removed.

The through-via TH may electrically connect the cell interconnection line 185 and the circuit interconnection line 280. The through-via TH may be electrically separated from the plate layer 101 by the substrate insulating layer 121. The through-via TH may have bent portions corresponding to those of the first to fourth channel portions CH1, CH2, CH3 and CH4 of the channel structures CH (see FIG. 2A). However, in some example embodiments, the through-via TH may not have the bent portions and may extend at a constant slope from an upper end to a lower end.

The first and second horizontal conductive layers 102 and 104 may be sequentially stacked and disposed on the upper surface of the plate layer 101 in the first region R1. The first and second horizontal conductive layers 102 and 104 may be included in a common source structure along with the plate layer 101, and may function as a common source line of the semiconductor device 100e. The first horizontal conductive layer 102 may be directly connected to the channel layer 140 in a lower portion of the channel structures CH. The first and second horizontal conductive layers 102 and 104 may include a semiconductor material, and may include, for example, polycrystalline silicon. In this case, at least the first horizontal conductive layer 102 may be a layer doped with impurities of the same conductive type as the plate layer 101.

The horizontal insulating layer 110 may be disposed on the plate layer 101 on the same level as that of the first horizontal conductive layer 102 in at least portions of the second to fourth regions R2, R3 and R4. The horizontal insulating layer 110 may include first and second horizontal insulating layers alternately stacked on the plate layer 101. The horizontal insulating layer 110 may be layers remaining after a portion of the semiconductor device 100e is replaced with the first horizontal conductive layer 102 during a manufacturing process of the semiconductor device 100e. The horizontal insulating layer 110 may include silicon oxide, silicon nitride, silicon carbide, or silicon oxynitride. The first horizontal insulating layer and the second horizontal insulating layer may include different insulating materials.

The substrate insulating layer 121 may be disposed to penetrate through the plate layer 101, the horizontal insulating layer 110 and the second horizontal conductive layer 104 in the fourth region R4. The substrate insulating layer 121 may include an insulating material, and may include, for example, silicon oxide, silicon nitride, silicon carbide, or silicon oxynitride.

The second semiconductor structure S2 may include a substrate 201, source/drain regions 205 and element isolating layers 210 in the substrate 201, circuit elements 220 disposed on the substrate 201, a peripheral region insulating layer 290, circuit contact plugs 270, and circuit interconnection lines 280.

The substrate 201 may have a lower surface extending in the X-direction and the Y-direction. An active region may be defined by the element isolating layers 210 in the substrate 201. The source/drain regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include planar transistors. Each of the circuit elements 220 may include a circuit gate dielectric layer 222, a spacer layer 224, and a circuit gate electrode 225. The source/drain regions 205 may be disposed as source/drain regions in the substrate 201 on both (i.e., opposite) sides of the circuit gate electrode 225.

The peripheral region insulating layer 290 may be disposed on (e.g., to cover and/or overlap) the circuit elements 220 on an upper surface of the substrate 201. The peripheral region insulating layer 290 may include a plurality of insulating layers formed in different process operations. The peripheral region insulating layer 290 may be formed of an insulating material.

The circuit contact plugs 270 and the circuit interconnection lines 280 may be included in a circuit interconnection structure electrically connected to the circuit elements 220 and the source/drain regions 205. The circuit contact plugs 270 may have a cylindrical shape, and the circuit interconnection lines 280 may have a line shape. An electrical signal may be applied to the circuit element 220 by the circuit contact plugs 270 and the circuit interconnection lines 280. For example, the circuit elements 220 may be connected to the gate electrodes 130 and the channel structures CH through the circuit interconnection structure including the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270 and may be disposed in a plurality of layers. The circuit contact plugs 270 and the circuit interconnection lines 280 may include a conductive material, and may include, for example, tungsten (W), copper (Cu), and/or aluminum (Al), and each component may further include a diffusion barrier. In example embodiments, the number of layers of the circuit contact plugs 270 and the circuit interconnection lines 280 may be variously changed.

Referring to FIG. 8B, unlike the example embodiment of FIG. 8A, a semiconductor device 100f may have a structure in which the first semiconductor structure S1 and the second semiconductor structure S2 are bonded. Accordingly, the first semiconductor structure S1 may further include first bonding vias 195, first bonding metal layers 198 and a first bonding insulating layer 199, and the second semiconductor structure S2 may further include second bonding vias 295, second bonding metal layers 298 and a second bonding insulating layer 299.

The first bonding vias 195, the first bonding metal layers 198 and the first bonding insulating layer 199 may be included in a first bonding structure of the first semiconductor structure S1. The first bonding vias 195 may be disposed below the cell interconnection lines 185, and the first bonding metal layers 198 may be connected to the first bonding vias 195. The first bonding metal layers 198 may have a lower surface thereof exposed to a lower surface of the first semiconductor structure S1. The first bonding metal layers 198 may be bonded and connected to the second bonding metal layers 298 of the second semiconductor structure S2. The first bonding vias 195 and the first bonding metal layers 198 may include a conductive material, and may include, for example, copper (Cu). The first bonding insulating layer 199 may form a dielectric-to-dielectric bond with the second bonding insulating layer 299 of the second semiconductor structure S2. The first bonding insulating layer 199 may include, for example, at least one of SiO, SiN, SiCN, SiOC, SiON, or SiOCN.

The second bonding vias 295, the second bonding metal layers 298, and the second bonding insulating layer 299 may be included in the second bonding structure, and may be disposed on at least a portion of a circuit interconnection line 280 in an uppermost portion. The second bonding vias 295 may have a cylindrical shape, and the second bonding metal layers 298 may have a pad shape having a circular shape on a plane or a relatively short line shape. Upper surfaces of the second bonding metal layers 298 may be exposed to an upper surface of the second semiconductor structure S2. The second bonding vias 295 and the second bonding metal layers 298 may provide electrical connection paths with the first semiconductor structure S1. In example embodiments, some of the second bonding metal layers 298 may not be connected to the circuit interconnection lines 280 and may be disposed only for bonding. The second bonding vias 295 and the second bonding metal layers 298 may include a conductive material, for example, copper (Cu). The second bonding insulating layer 299 may be disposed to have a predetermined thickness from a lower surface of the peripheral region insulating layer 290. The second bonding insulating layer 299 may be a layer for dielectric-dielectric bonding with the first bonding insulating layer 199 of the first semiconductor structure S1. The second bonding insulating layer 299 may also function as a diffusion barrier for the second bonding metal layers 298, and may include, for example, at least one of SiO, SiN, SiCN, SiOC, SiON, or SiOCN.

The first and second semiconductor structures S1 and S2 may be bonded to each other by the bonding of the first bonding metal layers 198 and the second bonding metal layers 298 and the bonding of the first bonding insulating layer 199 and the second bonding insulating layer 299. The bonding of the first bonding metal layers 198 and the second bonding metal layers 298 may be, for example, copper (Cu)-to-copper (Cu) bonding, and the bonding of the first bonding insulating layer 199 and the second bonding insulating layer 299 may be, for example, dielectric-to-dielectric bonding, such as SiCN—SiCN bonding. The first and second semiconductor structures S1 and S2 may be bonded by hybrid bonding including copper (Cu)-to-copper (Cu) bonding and dielectric-to-dielectric bonding.

The first and second semiconductor structures S1 and S2 may be packaged in a form in which the second semiconductor structure S2 is disposed below the first semiconductor structure S1, as illustrated in FIGS. 8A and 8B. In some other example embodiments, the first and second semiconductor structures S1 and S2 may be packaged in a form in which the second semiconductor structure S2 is disposed above the first semiconductor structure S1, in a state in which the upper portion and the lower portion are reversed.

FIGS. 9A to 9S are schematic cross-sectional views illustrating a method of manufacturing a semiconductor device according to example embodiments. FIGS. 9A to 9S illustrate cross-sections corresponding to FIGS. 2A and 8B.

Referring to FIG. 9A, first, a manufacturing process of the first semiconductor structure S1 (see FIG. 8B) may begin. The sacrificial insulating layers 118 and the interlayer insulating layers 120 may be alternately stacked on a base substrate SUB to form a mold structure PS and vertical sacrificial structures VS penetrating therethrough, and a first cell region insulating layer 192 may be formed.

The base substrate SUB is a layer removed through a subsequent process and may be a semiconductor substrate such as a silicon (Si) wafer. A first mold stack structure PS1 of the mold structure PS may be formed first, and then a portion of the vertical sacrificial structures VS penetrating therethrough may be formed, and then a second mold stack structure PS2 may be formed and a portion of the vertical sacrificial structures VS penetrating therethrough may be formed. In the same manner, the third and fourth mold stack structures PS3 and PS4 and a portion of the vertical sacrificial structures VS may be formed.

The sacrificial insulating layers 118 may be a layer replaced with gate electrodes 130 (see FIG. 2A) through a subsequent process. The sacrificial insulating layers 118 may be formed of a material different from the interlayer insulating layers 120, and may be formed of a material that may be etched with etch selectivity under specific etching conditions with respect to the interlayer insulating layers 120. For example, the interlayer insulating layer 120 may be formed of at least one of silicon oxide or silicon nitride, and the sacrificial insulating layers 118 may be formed of a material different from the interlayer insulating layer 120 selected from silicon, silicon oxide, silicon carbide, and silicon nitride. In example embodiments, thicknesses of the interlayer insulating layers 120 may not all be the same. The thicknesses of the interlayer insulating layers 120 and the sacrificial insulating layers 118 and the number of films included in the interlayer insulating layers 120 and the sacrificial insulating layers 118 may be variously changed from those illustrated.

The vertical sacrificial structures VS may be formed in positions corresponding to the channel structures CH and the dummy vertical structures DH of FIG. 2A, and the gate separation regions MS of FIG. 2B. The vertical sacrificial structures VS may be formed, for example, to have the same size as the channel structures CH. The vertical sacrificial structures VS may include, for example, carbon (C), but the present disclosure is not limited thereto.

Referring to FIG. 9B, first to third mask layers ML1, ML2 and ML3 may be formed on the first cell region insulating layer 192.

The first to third mask layers ML1, ML2 and ML3 may be sequentially stacked on the first cell region insulating layer 192. The first and second mask layers ML1 and ML2 may be hard mask layers and may include different materials. For example, the first mask layer ML1 may include polycrystalline silicon, and the second mask layer ML2 may include silicon oxide. The third mask layer ML3 may be a photoresist layer, and may be, for example, a positive photoresist layer in which an exposed region is dissolved by a developer.

Referring to FIG. 9C, openings OP may be formed in the first to third mask layers ML1, ML2 and ML3.

First, the third mask layer ML3 may be patterned by a photolithography process, and then the first and second mask layers ML1 and ML2 may be etched using the patterned third mask layer ML3, thus forming the openings OP. The openings OP may be formed to correspond to the first and second contact plugs MC1 and MC2 of FIG. 2A. Lower ends of the openings OP may be disposed in the first cell region insulating layer 192. However, in example embodiments, a level of the lower ends of the openings OP in the first cell region insulating layer 192 may be variously changed. After the openings OP are formed, the third mask layer ML3 may be removed.

Referring to FIG. 9D, a fourth mask layer ML4 may be formed on the second mask layer ML2.

The fourth mask layer ML4 may be a photoresist layer, and may be, for example, a negative photoresist layer in which an unexposed region is dissolved by a developer. The fourth mask layer ML4 may be in (e.g., may fill) the openings OP of the first and second mask layers ML1 and ML2.

Referring to FIG. 9E, the fourth mask layer ML4 may be patterned through a photolithography process.

The fourth mask layer ML4 may be exposed in a region corresponding to some of the openings OP, and the exposed region may remain, and some of the openings OP in the unexposed region may be opened. In this operation, for example, in FIG. 2A, the corresponding first and second contact plugs MC1 and MC2 may be connected to a Nth gate electrode 130 from the upper portion, in which case the openings OP corresponding to cases in which a last digit is 1 when the N is converted to binary may be opened.

Referring to FIG. 9F, a unit contact liner layer 150_U may be formed on the fourth mask layer ML4.

The unit contact liner layer 150_U may extend along sidewalls and bottom surfaces of the open openings OP. A thickness of the unit contact liner layer 150_U may be, for example, in a range of about 1 nm to about 5 nm, but is not limited thereto. The unit contact liner layer 150_U may include an insulating material, for example, at least one of SiO, SiCN, SiOC, SiON, or SiOCN. In some example embodiments, the unit contact liner layer 150_U may be formed of a material that may be etched together with the first mask layer ML1 under the same etching conditions.

Referring to FIG. 9G, a first etching process may be performed using the first, second, and fourth mask layers ML1, ML2 and ML4.

In the bottom surfaces of the open openings OP, the unit contact liner layer 150_U and the first cell region insulating layer 192 may be etched. The first etching process may be, for example, a dry etching process. For example, the first cell region insulating layer 192 below the openings OP may be etched entirely, and an uppermost sacrificial insulating layer 118 may be exposed through the bottom surfaces of the openings OP. However, in some example embodiments, such as the example embodiment of FIG. 5A, the etching process may be performed at a depth at which the first cell region insulating layer 192 partially remains. The unit contact liner layer 150_U may remain on sidewalls of the openings OP, thus forming the contact liner layer 150.

Referring to FIG. 9H, a fifth mask layer ML5 may be formed, a unit contact liner layer 150_U may be formed, and a second etching process may be performed.

First, the fourth mask layer ML4 may be removed, and the processes described above with reference to FIGS. 9D to 9G may be performed similarly. The fifth mask layer ML5 may be a photoresist layer, and may be, for example, a negative photoresist layer. By a photolithography process, for example, in FIG. 2A, the corresponding first and second contact plugs MC1 and MC2 may be connected to the Nth gate electrode 130 from the upper portion, in which case the openings OP corresponding to cases in which a second digit from the last is 1 when the N is converted to binary may be opened. Next, the unit contact liner layer 150_U may be formed, and portions of two sacrificial insulating layers 118 and two interlayer insulating layers 120 may be removed from the upper portion through the second etching process. The sacrificial insulating layers 118 may be exposed through the bottom surfaces of the openings OP. However, in some example embodiments, such as the example embodiment of FIG. 5A, the etching process may be performed at a depth at which a portion (e.g., a lower portion) of the interlayer insulating layer 120 remains.

In the openings OP in which the first and second etching processes are both performed, portions of the unit contact liner layers 150_U may be partially stacked. Accordingly, portions of the contact liner layers 150 may have a shape in which a thickness thereof increases on a level corresponding to a lower end of the openings OP in FIG. 9F.

In some example embodiments, as the etching process is repeated, a further inclination may occur in the upper regions of the openings OP. In some example embodiments, in this case, at least portions of the contact liner layers 150 may be removed on the sidewalls of the second mask layer ML2 exposed through the openings OP.

Referring to FIG. 9I, a sixth mask layer ML6 may be formed, a unit contact liner layer 150_U may be formed, and a third etching process may be performed.

First, the fifth mask layer ML5 may be removed, and the processes described above with reference to FIGS. 9D to 9G may be performed similarly. The sixth mask layer ML6 may be a photoresist layer, and may be, for example, a negative photoresist layer. By a photolithography process, for example, in FIG. 2A, the corresponding first and second contact plugs MC1 and MC2 may be connected to the Nth gate electrode 130 from the upper portion, in which case the openings OP corresponding to cases in which a third digit from the last is 1 when the N is converted to binary may be opened. Next, a unit contact liner layer 150_U may be formed, and portions of four sacrificial insulating layers 118 and four interlayer insulating layers 120 may be removed from the upper portion through the third etching process.

In the openings OP in which two or more of the first to third etching processes are performed, the contact liner layers 150 may include regions having different thicknesses.

Referring to FIG. 9J, a seventh mask layer ML7 may be formed, a unit contact liner layer 150_U may be formed, and a fourth etching process may be performed.

First, the sixth mask layer ML6 may be removed, and the processes described above with reference to FIGS. 9D to 9G may be performed similarly. The seventh mask layer ML7 may be a photoresist layer, and may be, for example, a negative photoresist layer. By a photolithography process, for example, in FIG. 2A, the corresponding first and second contact plugs MC1 and MC2 may connected to the Nth gate electrode 130 from the upper portion, in which case the openings OP corresponding to cases in which a fourth digit from the last is 1 when the N is converted to binary may be opened. Next, the unit contact liner layer 150_U may be formed, and portions of eight sacrificial insulating layers 118 and eight interlayer insulating layers 120 may be removed from the upper portion through the fourth etching process.

In the openings OP in which two or more etching processes among the first to fourth etching processes are performed, the contact liner layers 150 may include regions having different thicknesses.

Referring to FIG. 9K, an eighth mask layer ML8 may be formed, a unit contact liner layer 150_U may be formed, and a fifth etching process may be performed.

First, the seventh mask layer ML7 may be removed, and the processes described above with reference to FIGS. 9D to 9G may be performed similarly. The eighth mask layer ML8 may be a photoresist layer, for example, a negative photoresist layer. By a photolithography process, for example, in FIG. 2A, the corresponding first and second contact plugs MC1 and MC2 may be connected to the Nth gate electrode 130 from the upper portion, in which case the openings OP corresponding to cases in which a fifth digit from the last is 1 when the N is converted to binary may be opened. Next, the unit contact liner layer 150_U may be formed, and portions of 16 sacrificial insulating layers 118 and 16 interlayer insulating layers 120 may be removed from the upper portion through the fifth etching process.

In the openings OP in which two or more etching processes of the first to fifth etching processes are performed, the contact liner layers 150 may include regions having different thicknesses. In example embodiments, in the contact liner layers 150, first formed regions thereof may be partially removed in a subsequent etching process while repeating the etching process.

In this manner, by forming the unit contact liner layer 150_U before performing the first to fifth etching processes, upper regions of the openings OP may be prevented from being excessively expanded, thereby controlling diameters of the first and second contact plugs MC1 and MC2 of FIG. 2A that are finally formed. Additionally, damage such as the second mask layer ML2 being broken may be prevented. Accordingly, distortion of the shapes of the first and second contact plugs MC1 and MC2 may be prevented even when the etching process is performed multiple times.

Referring to FIG. 9L, the first, second and eighth mask layers ML1, ML2 and ML8 may be removed.

First, the eighth mask layer ML8 may be removed through an ashing and stripping process, and the second mask layer ML2 and the first mask layer ML1 may be removed sequentially by performing an etching process and/or a planarization process. The contact liner layers 150 formed on the sidewalls of the openings OP of the first mask layer ML1 may be removed during the repeated etching processes, or may be removed through a separate process, or may be removed together with the first mask layer ML1.

Through the processes described above, the openings OP having different depths may be finally formed in the mold structure PS. Depending on the number of layers of the sacrificial insulating layers 118 stacked on the mold structure PS, the processes of etching the 2ⁿ (where n=0, 1, 2, . . . ) sacrificial insulating layers 118 as described above may be repeatedly performed. Although it was described that the first to fifth etching processes are performed sequentially from the case in which n is 0, the present disclosure is not limited thereto, and in some example embodiments, the order of the etching processes may be changed in various manners, and accordingly, levels of points at which a thickness of the contact liner layers 150 is changed may also be changed in various manners.

Referring to FIG. 9M, preliminary contact insulating layers 160P and contact sacrificial layers 129 may be formed in the openings OP.

The preliminary contact insulating layers 160P may be formed conformally on (e.g., to cover and/or overlap) the sidewalls and the bottom surfaces of the openings OP. For example, the preliminary contact insulating layers 160P may be formed using an atomic layer deposition (ALD) or chemical vapor deposition (CVD) process.

The contact sacrificial layers 129 may be formed in (e.g., to fill) the openings OP on the preliminary contact insulating layers 160P. The contact sacrificial layers 129 may include a different material from the preliminary contact insulating layers 160P, and may include, for example, carbon (C).

Referring to FIG. 9N, a portion of the vertical sacrificial structures VS may be removed to form channel structures CH.

A mask layer exposing only a region corresponding to the channel structures CH in the first region R1 may be formed, and the exposed vertical sacrificial structures VS may be removed to form channel holes. At least a portion of the channel dielectric layer 145, the channel layer 140, the channel-filled insulating layer 147 and the channel pad 149 may be sequentially deposited in the channel holes, thus forming the channel structures CH.

The channel dielectric layer 145 may be formed to have a uniform thickness using an ALD or CVD process. In this operation, the channel dielectric layer 145 may be formed entirely or partially, and a portion vertically extending to the plate layer 101 along the channel structures CH may be formed in this operation. The channel layer 140 may be formed on the channel dielectric layer 145 in the channel holes. The channel-filled insulating layer 147 may be formed in (e.g., to fill) the channel holes and may be an insulating material. The channel pad 149 may be formed of a conductive material, and may be formed of, for example, polycrystalline silicon.

Referring to FIG. 9O, a portion of the vertical sacrificial structures VS may be removed, a dummy vertical structure DH may be formed, and the sacrificial insulating layers 118 may be removed, and gate electrodes 130 may be formed.

In the second and third regions R2 and R3, a mask layer exposing a region corresponding to the dummy vertical structures DH may be formed, and the exposed vertical sacrificial structures VS may be removed, thus forming dummy holes. A process of expanding the dummy holes by partially removing the mold structure PS around the dummy holes may be performed. The expanded dummy holes may be filled with an insulating material, thus forming the dummy vertical structures DH.

Next, the vertical sacrificial structures VS may be removed from positions corresponding to the gate separation regions MS of FIG. 1, thus forming vertical holes. The mold structure PS may be partially removed around the vertical holes, so that the vertical holes may be expanded so that the vertical holes are connected to each other, thereby forming trench-shaped openings corresponding to the gate separation regions MS. The sacrificial insulating layers 118 exposed through the openings may be removed. The sacrificial insulating layers 118 may be selectively removed, for example, using wet etching, with respect to the interlayer insulating layers 120, the channel structures CH, the dummy vertical structures DH, and the preliminary contact insulating layers 160P.

The gate electrodes 130 may be formed by depositing a conductive material in regions from which the sacrificial insulating layers 118 are removed. The conductive material may include a metal, polycrystalline silicon, or a metal silicide material. In the gate electrodes 130, the gate conductive layers 135 (see FIG. 4) may be formed after forming the gate barrier layers 132 (see FIG. 4). In some example embodiments, a portion of the channel dielectric layer 145 (see FIG. 4) may be formed before forming the gate electrodes 130. Accordingly, a gate structure GS including first to fourth stack structures GS1, GS2, GS3 and GS4 may be formed. After forming the gate electrodes 130, an insulating material may be deposited in the openings, thus forming gate separation regions MS (see FIGS. 1 and 2B).

Referring to FIG. 9P, the contact sacrificial layers 129 may be removed, and portions of the preliminary contact insulating layers 160P may be removed, thus forming contact spacers 160.

The contact sacrificial layers 129 may be selectively removed with respect to the preliminary contact insulating layers 160P. Next, some of the preliminary contact insulating layers 160P exposed through the openings OP may be removed from the bottom surfaces of the openings OP. When the preliminary contact insulating layers 160P are removed, the exposed gate electrodes 130 may also be partially recessed from upper surfaces thereof. Accordingly, the contact spacers 160 disposed only on the sidewalls of the openings OP may be formed.

Referring to FIG. 9Q, a conductive material may be deposited in the openings OP to form first and second contact plugs MC1 and MC2, and first and second upper separation regions SS1 (see FIG. 1) and SS2 may be formed.

The first and second contact plugs MC1 and MC2 may be formed together by depositing a conductive material in the openings OP. The first and second contact plugs MC1 and MC2 may be physically connected to the gate electrodes 130.

In regions corresponding to the first and second upper separation regions SS1 and SS2 of FIG. 1, respectively, a portion of the gate electrode structure GS may be removed to penetrate through upper gate electrodes 130U, thus forming trenches. Trenches corresponding to the first upper separation regions SS1, among the trenches, may be formed to extend while cutting a portion of the channel structures CH in the first region R1. The trenches may be filled with an insulating material and a planarization process may be performed to form the first and second upper separation regions SS1 and SS2. In some example embodiments, the first and second upper separation regions SS1 and SS2 may be formed in different process operations.

Referring to FIG. 9R, the studs 180, the cell interconnection lines 185 and the first bonding structure may be formed to form the first semiconductor structure S1, and after the second semiconductor structure S2 is formed, the first semiconductor structure S1 and the second semiconductor structure S2 may be bonded to each other.

The studs 180 may be formed by forming stud holes penetrating through the second cell region insulating layer 194 and exposing the channel structures CH and the first and second contact plugs MC1 and MC2, and then filling the stud holes with a conductive material. The cell interconnection lines 185 may be formed on the studs 180.

The first bonding vias 195 and the first bonding metal layers 198 included in the first bonding structure may be formed by further forming a second cell region insulating layer 194 on the cell interconnection lines 185 and a first bonding insulating layer 199, and then removing a portion of the formed layers and depositing a conductive material in the removed portion. Lower surfaces of the first bonding metal layers 198 may be exposed from the second cell region insulating layer 194. Accordingly, the first semiconductor structure S1 may be prepared.

The second semiconductor structure S2 may be prepared by forming circuit elements 220, circuit interconnection structures, and the second bonding structure on the substrate 201.

Element isolating layers 210 may be formed in the substrate 201, and a circuit gate dielectric layer 222 and a circuit gate electrode 225 may be sequentially formed on the substrate 201. The element isolating layers 210 may be formed, for example, by a shallow trench isolation (STI) process. The circuit gate dielectric layer 222 and the circuit gate electrode 225 may be formed using ALD or CVD. The circuit gate dielectric layer 222 may be formed of silicon oxide, and the circuit gate electrode 225 may be formed of at least one of polycrystalline silicon or a metal silicide layer, but the present disclosure is not limited thereto. A spacer layer 224 and source/drain regions 205 may be formed on both (i.e., opposite) sidewalls of the circuit gate dielectric layer 222 and the circuit gate electrode 225. According to example embodiments, the spacer layer 224 may be formed of a plurality of layers. The source/drain regions 205 may be formed by performing an ion implantation process.

The circuit contact plugs 270 of the circuit interconnection structure and the second bonding vias 295 of the second bonding structure may be formed by forming a portion of the peripheral region insulating layer 290, and then etching and removing the formed portion, and filling the removed portion with a conductive material. The circuit interconnection lines 280 of the circuit interconnection structure and the second bonding metal layers 298 of the second bonding structure may be formed, for example, by depositing a conductive material and then patterning the conductive material. The second bonding metal layers 298 may be formed so that a lower surface thereof is exposed through the second bonding insulating layer 299.

The peripheral region insulating layer 290 may be formed of a plurality of insulating layers. The peripheral region insulating layer 290 may be partially formed in each operation of forming the circuit interconnection structure and the second bonding structure. By this operation, the second semiconductor structure S2 may be prepared.

The first semiconductor structure S1 and the second semiconductor structure S2 may be connected to each other by bonding the first bonding metal layers 198 and the second bonding metal layers 298 by applying pressure. At the same time, the first bonding insulating layers 199 and the second bonding insulating layers 299 may also be bonded by applying pressure. The first semiconductor structure S1 may be flipped over (i.e., inverted over) the second semiconductor structure S2 so that the first bonding metal layers 198 face downwardly, and then the bonding may be performed.

Referring to FIG. 9S, the base substrate SUB may be removed, and the channel layers 140 may be exposed.

In the bonding structure of the first semiconductor structure S1 and the second semiconductor structure S2, the base substrate SUB may be removed, and a portion of the exposed channel dielectric layers 145 (see FIG. 4) may be removed, thereby exposing the channel layers 140.

Next, referring back to FIG. 8B, the semiconductor device 100f may be manufactured by forming a plate layer 101 connected to the channel layers 140. In some example embodiments, the plate layer 101 may be formed as a conformal layer along upper portions of the channel structures CH and upper portions of the dummy vertical structures DH.

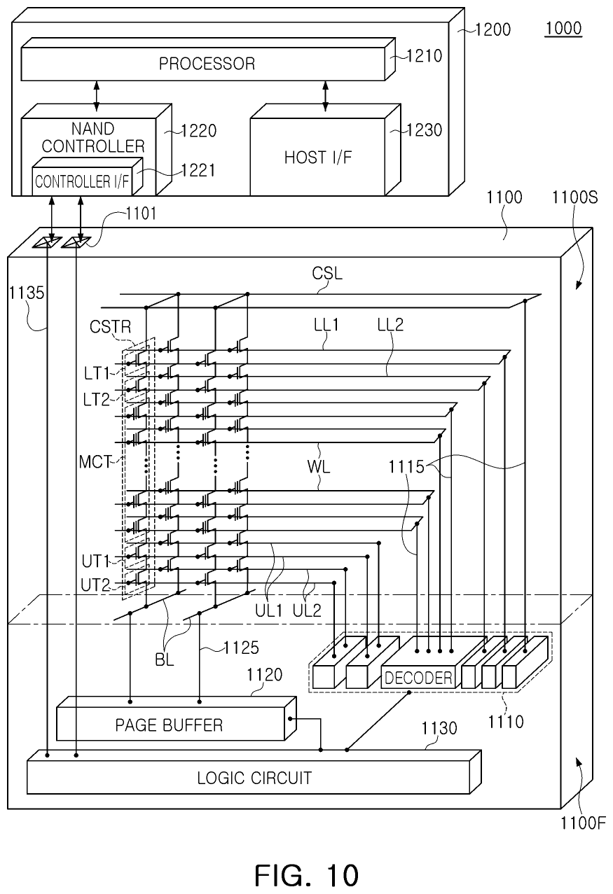

FIG. 10 is a schematic view of a data storage system including a semiconductor device according to example embodiments.

Referring to FIG. 10, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive (SSD) device, a Universal Serial Bus (USB), a computing system, a medical device, or a communication device, including one or more semiconductor devices 1100.

The semiconductor device 1100 (which may also be referred to as a semiconductor storage device 1100) may be a nonvolatile memory device, for example, a NAND flash memory device as described above with reference to FIGS. 1 to 8B. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL. In some example embodiments, the first structure 1100F may include the second semiconductor structure S2 described above with reference to FIGS. 8A and 8B, and the second structure 1100S may include the first semiconductor structure S1 described above with reference to FIGS. 8A and 8B, but the present disclosure is not limited thereto.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed depending on the example embodiments.

In example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground select transistor LT2 which are serially connected. The upper transistors UT1 and UT2 may include a string select transistor UT1 and an upper erase control transistor UT2 which are serially connected. At least one of the lower erase control transistor LT1 and the upper erase control transistor UT2 may be used for an erase operation of erasing data stored in the memory cell transistors MCT by utilizing the gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection line 1135 that extends from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a NAND interface 1221 processing communication with the semiconductor device 1100. Through the NAND interface 1221, a control command for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When receiving a control command from the external host through the host interface 1230, the processor 1210 may control the semiconductor device 1100 in response to the control command.

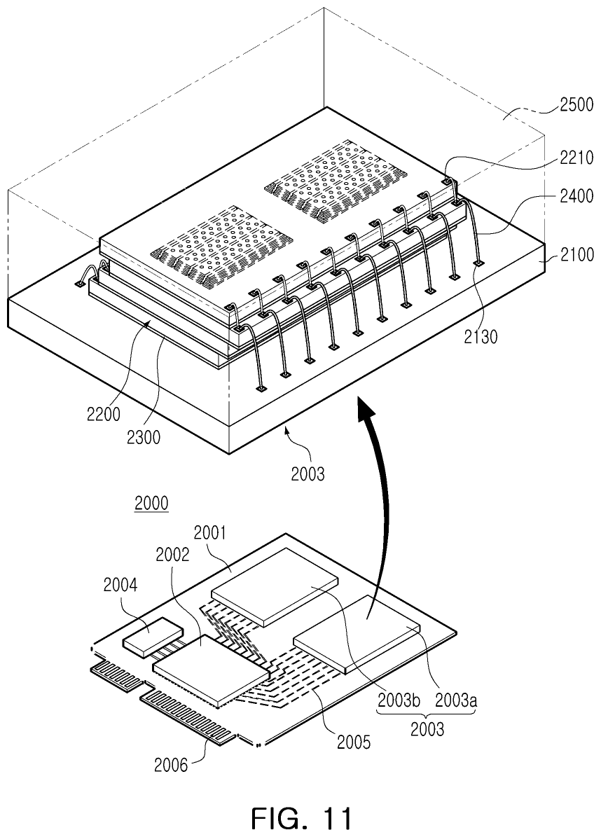

FIG. 11 is a perspective view schematically illustrating a data storage system including a semiconductor device according to example embodiments.

Referring to FIG. 11, a data storage system 2000 may include a main board 2001, a controller 2002 mounted on the main board 2001, one or more semiconductor packages 2003, and a DRAM 2004. The semiconductor package 2003 and the DRAM 2004 may be connected to each other with the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on the communication interface between the data storage system 2000 and the external host. In example embodiments, the data storage system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In example embodiments, the data storage system 2000 may operate by power supplied from the external host through the connector 2006. The data storage system 2000 may further include a Power Management Integrated Circuit (PMIC) distributing power supplied from the external host to the controller 2002 and the semiconductor package 2003.

The controller 2002 may write data to the semiconductor package 2003 or read data from the semiconductor package 2003, and may improve the operating speed of the data storage system 2000.

The DRAM 2004 may be a buffer memory to alleviate a speed difference between the semiconductor package 2003, which is a data storage space, and an external host. The DRAM 2004 included in the data storage system 2000 may also operate as a kind of cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 on (e.g., covering and/or overlapping) the semiconductor chips 2200 and the connection structure 2400 on the package substrate 2100.

The package substrate 2100 may be a printed circuit board (PCB) including package upper pads 2130. Each semiconductor chip 2200 may include an input/output pad 2210. The input/output pad 2210 may correspond to the input/output pad 1101 of FIG. 10. Each of the semiconductor chips 2200 may include the semiconductor device described above with reference to FIGS. 1 to 8B.

In example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to some other example embodiments, in each of the first and second semiconductor packages 2003a and 2003b, the semiconductor chips 2200 may be electrically connected to each other by a connection structure including a through silicon via (TSV) instead of the bonding wire-type connection structure 2400.

In some example embodiments, the controller 2002 and the semiconductor chips 2200 may be included in one package. In some further example embodiments, the controller 2002 and the semiconductor chips 2200 may be mounted on a separate interposer substrate different from the main substrate 2001, and the controller 2002 and the semiconductor chips 2200 may be connected to each other by interconnection lines formed on the interposer substrate.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor device, comprising:
a plate layer;
gate electrodes spaced apart from each other and stacked in a first direction perpendicular to an upper surface of the plate layer, the gate electrodes extending in a second direction perpendicular to the first direction along first and second regions;
channel structures in the first region and extending in the first direction into the gate electrodes;
contact plugs extending in the first direction and electrically connected to the gate electrodes, respectively, in the second region; and
contact liner layers on side surfaces of the contact plugs, respectively,
wherein portions of the contact plugs extend into at least one of the gate electrodes, and
wherein the contact liner layers comprise:
a first contact liner layer on a side surface of a first one of the contact plugs, the first contact liner layer having a maximum thickness in the second direction as a first thickness; and
a second contact liner layer on a side surface of a second one of the contact plugs, the second contact liner layer including a lower region having the first thickness and an upper region having a second thickness in the second direction that is greater than the first thickness.

2. The semiconductor device of claim 1, wherein an inner side surface of the lower region of the second contact liner layer and an inner side surface of the upper region of the second contact liner layer are collinear with each other, and
wherein the second contact liner layer includes a step portion between an outer side surface of the lower region of the second contact liner layer and an outer side surface of the upper region of the second contact liner layer.

3. The semiconductor device of claim 1, wherein the second contact liner layer further includes an intermediate region between the lower region and the upper region, the intermediate region having a third thickness in the second direction that is greater than the first thickness and less than the second thickness.

4. The semiconductor device of claim 1, wherein a first distance between the first one of the contact plugs and the upper surface of the plate layer is different from a second distance between the second one of the contact plugs and the upper surface of the plate layer.

5. The semiconductor device of claim 1, wherein the contact liner layers further comprise a third contact liner layer on a side surface of a third one of the contact plugs, the third contact liner layer including a lower region having the first thickness and an upper region having the second thickness, and
wherein a first distance between the second one of the contact plugs and the upper surface of the plate layer is different from a second distance between the third one of the contact plugs and the upper surface of the plate layer.

6. The semiconductor device of claim 1, further comprising contact spacers between the contact plugs and the contact liner layers, respectively.

7. The semiconductor device of claim 6, wherein the contact spacers include a different insulating material from the contact liner layers.

8. The semiconductor device of claim 6, wherein a respective one of the contact liner layers and a respective one of the contact spacers are both on a respective one of the side surfaces of the contact plugs, and
wherein a length of the respective one of the contact liner layers in the first direction is less than a length of the respective one of the contact spacers in the first direction.

9. The semiconductor device of claim 1, wherein the first contact liner layer extends a first length in the first direction, and the first one of the contact plugs extends a second length in the first direction, and
wherein the second length is at least twice the first length.

10. The semiconductor device of claim 1, wherein the first contact liner layer extends a first length in the first direction, and the second contact liner layer extends a second length in the first direction that is greater than the first length, and
wherein a first distance between the first one of the contact plugs and the upper surface of the plate layer is less than a second distance between the second one of the contact plugs and the upper surface of the plate layer.

11. The semiconductor device of claim 1, wherein a first distance between the upper region of the second contact liner layer and the upper surface of the plate layer is greater than a second distance between an upper surface of an uppermost one of the gate electrodes and the upper surface of the plate layer.

12. The semiconductor device of claim 1, further comprising a semiconductor structure including a substrate and circuit elements on the substrate and electrically connected to the gate electrodes and the channel structures,
wherein the plate layer is on the semiconductor structure.

13. The semiconductor device of claim 1, wherein the gate electrodes extend a same length in the second direction across the first and second regions.

14. A semiconductor device, comprising:
a plate layer;
gate electrodes spaced apart from each other and stacked in a first direction perpendicular to an upper surface of the plate layer;
channel structures extending in the first direction into the gate electrodes;
contact plugs extending in the first direction and electrically connected to the gate electrodes, respectively; and
contact liner layers on side surfaces of the contact plugs, respectively,
wherein portions of the contact plugs extend into at least one of the gate electrodes, and
wherein a first one of the contact liner layers includes a plurality of regions arranged in the first direction and having different thicknesses in a second direction perpendicular to the first direction, and the thicknesses of the plurality of regions decrease toward the plate layer.

15. The semiconductor device of claim 14, wherein a thickness of the first one of the contact liner layers in the second direction changes discontinuously between the plurality of regions.

16. The semiconductor device of claim 14, wherein the first one of the contact liner layers has a step portion on an outer side surface thereof between adjacent ones of the plurality of regions.

17. The semiconductor device of claim 14, wherein a number of the plurality of regions is in a range from two to ten.

18. The semiconductor device of claim 14, wherein the plurality of regions is a first plurality of regions,
wherein a second one of the contact liner layers includes a second plurality of regions arranged in the first direction and having different thicknesses in the second direction, and
wherein a first one of the first plurality of regions and a first one of the second plurality of regions are spaced apart from the upper surface of the plate layer by a same distance in the first direction and have different thicknesses in the second direction.

19. A data storage system, comprising:
a semiconductor storage device that comprises a first semiconductor structure including circuit elements, a second semiconductor structure on the first semiconductor structure, and an input/output pad electrically connected to the circuit elements; and
a controller electrically connected to the semiconductor storage device through the input/output pad and configured to control the semiconductor storage device,
wherein the second semiconductor structure comprises:
a plate layer;
gate electrodes spaced apart from each other and stacked in a first direction perpendicular to an upper surface of the plate layer;
channel structures extending in the first direction into the gate electrodes;
contact plugs extending in the first direction and electrically connected to the gate electrodes, respectively; and
contact liner layers on side surfaces of the contact plugs, respectively,
wherein portions of the contact plugs extend into at least one of the gate electrodes, and
wherein the contact liner layers comprise:
a first contact liner layer including a region having a first thickness in a second direction perpendicular to the first direction; and
a second contact liner layer including a lower region having the first thickness and an upper region having a second thickness in the second direction that is greater than the first thickness, the second contact liner layer having a different length from the first contact liner layer in the first direction.

20. The data storage system of claim 19, wherein the region of the first contact liner layer and the lower region of the second contact liner layer are spaced apart from the upper surface of the plate layer by different distances in the first direction.
